(19) United States
(12) Patent Application Publication
(10) Pub. No.: US 2023/0113299 A1
(43) Pub. Date: Apr. 13, 2023

(54) ENERGY STORAGE SYSTEM AND ENERGY SUPPLYING SYSTEM INCLUDING THE SAME

(71) Applicant: LG ELECTRONICS INC., Seoul (KR)

(72) Inventor: Sanghun KIM, Seoul (KR)

(73) Assignee: LG ELECTRONICS INC., Seoul (KR)

(21) Appl. No.: 17/555,211

(22) Filed: Dec. 17, 2021

(30) Foreign Application Priority Data
Oct. 12, 2021 (KR) 10-2021-0135131

(51) Int. Cl. H02J 9/00; H02J 3/32; H02J 7/00; H02J 3/00

(52) U.S. Cl. CPC H02J 9/005; H02J 3/32; H02J 7/0063; H02J 3/001; H02J 7/0048; H02J 7/00712; H02J 2300/24

(57) ABSTRACT

An energy storage system according to an embodiment of the present disclosure is connected to a grid power source and a photovoltaic panel, and includes: a battery configured to store electric energy received from the grid power source or the photovoltaic panel in a direct current form, or to output the stored electric energy to one or more loads; a grid relay configured to connect or block a power path connected to the grid power source; and a load relay configured to connect or block a power path connected to the load, wherein the grid relay is turned off when an error occurs in the grid power source, and the load relay is turned off when a state of charge of the battery is lower than an off-reference value.

### CROSS-REFERENCE TO RELATED APPLICATION

Pursuant to 35 U.S.C. § 119(a), this application claims the benefit of earlier filing date and right of priority to Korean Patent Application No. 10-2021-0135131, filed on Oct. 12, 2021, the contents of which are hereby incorporated by reference herein in its entirety.

### BACKGROUND OF THE INVENTION

### 1. Field of the Invention

The present disclosure relates to an energy storage system and an energy supplying system including the same, and more particularly, to a battery-based energy storage system and an operating method thereof, and an energy supplying system including the energy storage system and an operating method thereof.

### 2. Description of the Related Art

An energy storage system is a system that stores or charges external power, and outputs or discharges stored power to the outside. To this end, the energy storage system includes a battery, and a power conditioning system is used for supplying power to the battery or outputting power from the battery.

The energy storage system may be connected to a grid power to charge the battery. In addition, the energy storage system may be connected to a photovoltaic plant to configure a power system. For example, Patent Registration No. 10-1203842 discloses a technology of first supplying power generated by a generator (means a power generation module such as PV) to a power load, and supplying the remaining power to a grid or a battery. Here, the grid may refer to a power supply network or the like. Patent Registration No. 10-1203842 improves the efficiency of energy management, by efficiently connecting the generation, supply, storage, and consumption of power using a grid, a photovoltaic plant, and an energy storage system according to a situation.

Patent Registration No. 10-1203842 discloses an energy storage system operated as an uninterruptible power supply (UPS) by supplying power to a main power load from a battery after blocking a power network connection during an outage of power network. As described above, the energy storage system can supply stable power by previously storing a reserve power and then using the stored reserve power in case of an emergency such as a power outage of the grid.

In addition, distributed power plant such as photovoltaic power can also supply power to the load in the event of a power outage of the grid. Patent Publication No. 10-2013-0131149 discloses that, in the event of a power outage, some of the energy of distributed power plant such as photovoltaic power is recovered so that the energy is preferentially supplied to prioritized facilities.

However, if the power outage is prolonged, photovoltaic generation may be difficult due to weather, abnormal power supply to the power plant, etc., and if energy stored in the energy storage system is consumed, emergency energy supply may be stopped. Therefore, there is a need for a stable emergency energy supply method even during a long-term power outage.

### SUMMARY OF THE INVENTION

The present disclosure has been made in view of the above problems, and an object of the present disclosure is to provide an energy storage system that can be stably operated during a power outage.

Another object of the present disclosure is to provide an energy storage system capable of efficiently using energy during a power outage, and charging a battery.

Another object of the present disclosure is to provide an energy storage system capable of determining a situation in which a battery can be charged during a power outage.

Another object of the present disclosure is to provide an energy storage system capable of efficiently producing, storing, and managing energy by interworking with a photovoltaic generator.

Another object of the present disclosure is to provide an energy supplying system capable of responding to a long-term power outage by providing a means for multiply supplying emergency energy.

Another object of the present disclosure is to provide an energy supplying system capable of determining a situation in which photovoltaic power generation and battery charging are possible.

Another object of the present disclosure is to provide an energy supplying system capable of stably charging a battery from a photovoltaic generator, even if the energy stored in the battery is exhausted.

In order to achieve the above object, the energy storage system according to embodiments of the present disclosure may efficiently supply emergency power to essential loads by controlling relays when a power outage occurs.

In order to achieve the above object, the energy storage system according to embodiments of the present disclosure may efficiently respond to a grid power outage in conjunction with a photovoltaic panel.

In order to achieve the above object, the energy storage system according to embodiments of the present disclosure may efficiently use the energy stored in the battery during a power outage and recharge the battery, according to the state of charge of battery and the generation of photovoltaic power.

In accordance with an aspect of the present disclosure, an energy storage system includes: a battery configured to be connected to a grid power source and a photovoltaic panel, and to store electric energy received from the grid power source or the photovoltaic panel in a direct current form, or to output the stored electric energy to one or more loads; a grid relay configured to be able to connect or block a power path connected to the grid power source; and a load relay configured to be able to connect or block a power path connected to the load, wherein the grid relay is turned off when an error occurs in the grid power source, and the load relay is turned off when a state of charge of the battery is lower than an off-reference value.

The battery is charged with a power generated by the photovoltaic panel, when power is generated by the photovoltaic panel.

The load relay is turned on when the state of charge of the battery is higher than the off-reference value.

The load relay is turned on, when the state of charge of the battery is higher than an on-reference value set higher than the off-reference value.

The energy storage system further includes a power save mode in which only a preset minimum operation is performed, when no power is generated by the photovoltaic panel.

In a state of the power save mode, when a preset setting time is reached, a photovoltaic inverter driving signal is transmitted to a photovoltaic inverter that converts a power generated by the photovoltaic panel.

The photovoltaic inverter driving signal is a signal corresponding to a voltage when the grid power source is in a normal state.

The energy storage system further includes an illuminance sensor, wherein in a state of the power save mode, when an illuminance value detected by the illuminance sensor is higher than an illuminance reference value, the photovoltaic inverter driving signal is transmitted to the photovoltaic inverter converting a power generated by the photovoltaic panel.

The photovoltaic inverter driving signal is a signal corresponding to a voltage when the grid power source is in a normal state.

The energy storage system further includes an emergency power button, wherein in a state of the power save mode, when there is an input to the emergency power button, the photovoltaic inverter driving signal is transmitted to the photovoltaic inverter converting a power generated by the photovoltaic panel.

The photovoltaic inverter driving signal is a signal corresponding to a voltage when the grid power source is in a normal state.

The energy storage system further includes a controller for controlling the grid relay and the load relay so that, when an error occurs in the grid power source, the electric energy generated by the photovoltaic panel or stored in the battery is supplied to a preset load.

The energy storage system further includes: a power conditioning system configured to convert electrical characteristics for charging or discharging the battery; and a battery management system configured to monitor state information of the battery.

The energy storage system further includes a casing forming a space in which the battery, the power conditioning system, and the battery management system are disposed.

The energy storage system further includes a power management system for controlling the power conditioning system, wherein the power management system is disposed in an enclosure outside the casing.

The power management system controls the grid relay and the load relay so that, when an error occurs in the grid power source, the electric energy generated by the photovoltaic panel or stored in the battery is supplied to a preset load.

The grid relay and the load relay are disposed in the enclosure.

The energy storage system further includes a load panel connected to a preset essential load, wherein the load relay is connected to the load panel.

The off-reference value is set to be higher than a minimum state of charge in which the battery deteriorates and becomes in an unrecoverable state.

In accordance with another aspect of the present disclosure, an energy supplying system includes: a photovoltaic panel; and an energy storage system including a battery configured to store electric energy received from the grid power source or the photovoltaic panel in a direct current form, or to output the stored electric energy to one or more loads, a grid relay configured to be able to connect or block a power path connected to the grid power source, and a load relay configured to be able to connect or block a power path connected to the load, wherein the grid relay is turned off when an error occurs in the grid power source, and the load relay is turned off when a state of charge of the battery is lower than an off-reference value.

### BRIEF DESCRIPTION OF THE DRAWINGS

The above and other objects, features and advantages of the present disclosure will be more apparent from the following detailed description in conjunction with the accompanying drawings, in which:

FIGS. 1A and 1B are conceptual diagrams of an energy supplying system including an energy storage system according to an embodiment of the present disclosure;

FIG. 2 is a conceptual diagram of a home energy service system including an energy storage system according to an embodiment of the present disclosure;

FIG. 3A and 3B are diagrams illustrating an energy storage system installation type according to an embodiment of the present disclosure;

FIG. 4 is a conceptual diagram of a home energy service system including an energy storage system according to an embodiment of the present disclosure;

FIG. 5 is an exploded perspective view of an energy storage system including a plurality of battery packs according to an embodiment of the present disclosure;

FIG. 6 is a front view of an energy storage system in a state in which a door is removed;

FIG. 7 is a cross-sectional view of one side of FIG. 6;

FIG. 8 is a perspective view of a battery pack according to an embodiment of the present disclosure;

FIG. 9 is an exploded view of a battery pack according to an embodiment of the present disclosure;

FIG. 10 is a perspective view of a battery module according to an embodiment of the present disclosure;

FIG. 11 is an exploded view of a battery module according to an embodiment of the present disclosure;

FIG. 12 is a front view of a battery module according to an embodiment of the present disclosure;

FIG. 13 is an exploded perspective view of a battery module and a sensing substrate according to an embodiment of the present disclosure;

FIG. 14 is a perspective of a battery module and a battery pack circuit substrate according to an embodiment of the present disclosure;

FIG. 15A is one side view in a coupled state of FIG. 14;

FIG. 15B is the other side view in a coupled state of FIG. 14;

FIG. 16 is a conceptual diagram of an energy supplying system including an energy storage system according to an embodiment of the present disclosure;

FIG. 17 is a flowchart of a method of operating an energy storage system according to an embodiment of the present disclosure;

FIG. 18 is a conceptual diagram of an energy supplying system including an energy storage system according to an embodiment of the present disclosure;

FIG. 19 is a flowchart of a method of operating an energy storage system according to an embodiment of the present disclosure;

FIG. 20 is a flowchart of a method of operating an energy storage system according to an embodiment of the present disclosure;

FIG. 21 is a conceptual diagram of an energy supplying system including an energy storage system according to an embodiment of the present disclosure; and

FIG. 22 is a flowchart of a method of operating an energy storage system according to an embodiment of the present disclosure.

### DETAILED DESCRIPTION OF THE PREFERRED EMBODIMENTS

Hereinafter, embodiments of the present disclosure will be described in detail with reference to the accompanying drawings. However, it is obvious that the present disclosure is not limited to these embodiments and may be modified in various forms.

In the drawings, in order to clearly and briefly describe the present disclosure, the illustration of parts irrelevant to the description is omitted, and the same reference numerals are used for the same or extremely similar parts throughout the specification.

Hereinafter, the suffixes “module” and “unit” of elements herein are used for convenience of description and thus may be used interchangeably and do not have any distinguishable meanings or functions. Thus, the “module” and the “unit” may be interchangeably used.

It will be understood that, although the terms “first”, “second”, etc. may be used herein to describe various elements, these elements should not be limited by these terms. These terms are only used to distinguish one element from another element.

The top U, bottom D, left Le, right Ri, front F, and rear R used in drawings are used to describe a battery pack and an energy storage system including the battery pack, and may be set differently according to standard.

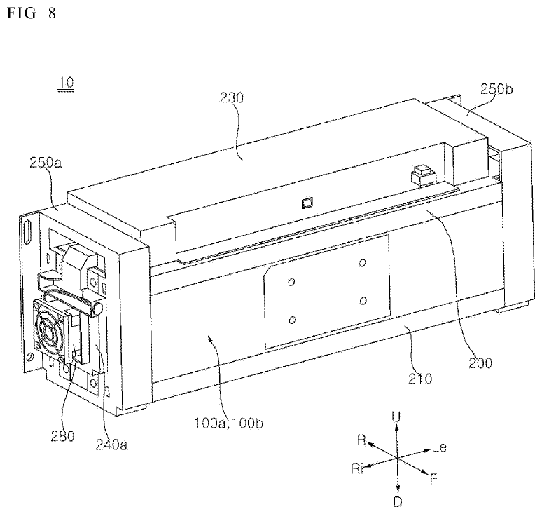

The height direction (h+, h−), length direction (1+, 1−), and width direction (w+, w−) of the battery module used in FIGS. 10 to 13 are used to describe the battery module, and may be set differently according to standard.

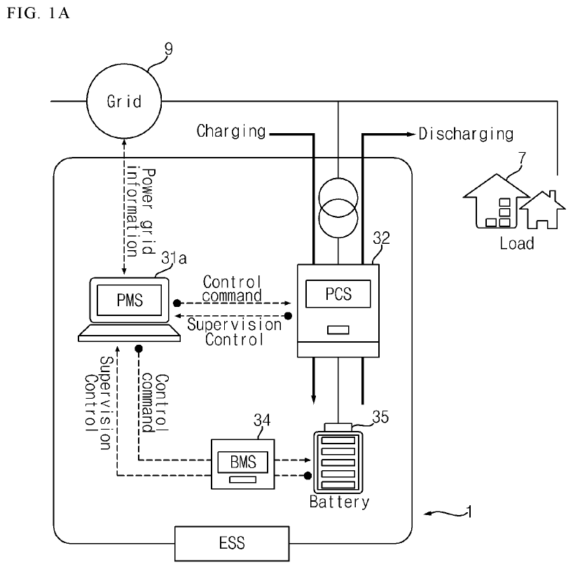

FIGS. 1A and 1B are conceptual diagrams of an energy supplying system including an energy storage system according to an embodiment of the present disclosure.

Referring to FIGS. 1A and 1B, the energy supplying system includes a battery 35-based energy storage system 1 in which electric energy is stored, a load 7 that is a power demander, and a grid 9 provided as an external power supply source.

The energy storage system 1 includes a battery 35 that stores (charges) the electric energy received from the grid 9, or the like in the form of direct current (DC) or outputs (discharges) the stored electric energy to the grid 9, or the like, a power conditioning system 32 (PCS) for converting electrical characteristics (e.g. AC/DC interconversion, frequency, voltage) for charging or discharging the battery 35, and a battery management system 34 (BMS) that monitors and manages information such as current, voltage, and temperature of the battery 35.

The grid 9 may include a power generation facility for generating electric power, a transmission line, and the like. The load 7 may include a home appliance such as a refrigerator, a washing machine, an air conditioner, a TV, a robot cleaner, and a robot, a mobile electronic device such as a vehicle and a drone, and the like, as a consumer that consumes power.

The energy storage system 1 may store power from an external in the battery 35 and then output power to the external. For example, the energy storage system 1 may receive DC power or AC power from the external, store it in the battery 35, and then output the DC power or AC power to the external.

Meanwhile, since the battery 35 mainly stores DC power, the energy storage system 1 may receive DC power or convert the received AC power to DC power and store it in the battery 35, and may convert the DC power stored in the battery 35, and may supply to the grid 9 or the load 7.

At this time, the power conditioning system 32 in the energy storage system 1 may perform power conversion and voltage-charge the battery 35, or may supply the DC power stored in the battery 35 to the grid 9 or the load 7.

The energy storage system 1 may charge the battery 35 based on power supplied from the system and discharge the battery 35 when necessary. For example, the electric energy stored in the battery 35 may be supplied to the load 7 in an emergency such as a power outage, or at a time, date, or season when the electric energy supplied from the grid 9 is expensive.

The energy storage system 1 has the advantage of being able to improve the safety and convenience of new renewable energy generation by storing electric energy generated from a new renewable energy source such as sunlight, and to be used as an emergency power source. In addition, when the energy storage system 1 is used, it is possible to perform load leveling for a load having large fluctuations in time and season, and to save energy consumption and cost.

The battery management system 34 may measure the temperature, current, voltage, state of charge, and the like of the battery 35, and monitor the state of the battery 35. In addition, the battery management system 34 may control and manage the operating environment of the battery 35 to be optimized based on the state information of the battery 35.

Meanwhile, the energy storage system 1 may include a power management system 31a (PMS) that controls the power conditioning system 32.

The power management system 31a may perform a function of monitoring and controlling the states of the battery 35 and the power conditioning system 32. The power management system 31a may be a controller that controls the overall operation of the energy storage system 1.

The power conditioning system 32 may control power distribution of the battery 35 according to a control command of the power management system 31a. The power conditioning system 32 may convert power according to the grid 9, a power generation means such as photovoltaic light, and the connection state of the battery 35 and the load 7.

Meanwhile, the power management system 31a may receive state information of the battery 35 from the battery management system 34. A control command may be transmitted to the power conditioning system 32 and the battery management system 34.

The power management system 31a may include a communication means such as a Wi-Fi communication module, and a memory. Various information necessary for the operation of the energy storage system 1 may be stored in the memory. In some embodiments, the power management system 31a may include a plurality of switches and control a power supply path.

The power management system 31a and/or the battery management system 34 may calculate the SOC of the battery 35 using various well-known SOC calculation methods such as a coulomb counting method and a method of calculating a state of charge (SOC) based on an open circuit voltage (OCV). The battery 35 may overheat and irreversibly operate when the state of charge exceeds a maximum state of charge. Similarly, when the state of charge is less than or equal to the minimum state of charge, the battery may deteriorate and become unrecoverable. The power management system 31a and/or the battery management system 34 may monitor the internal temperature, the state of charge of the battery 35, and the like in real time to control an optimal usage area and maximum input/output power.

As shown in FIG. 1B, the power management system 31a may operate under the control of an energy management system (EMS) 31b, which is an upper controller. The power management system 31a may control the energy storage system 1 by receiving a command from the energy management system 31b, and may transmit the state of the energy storage system 1 to the energy management system 31b. The energy management system 31b may be provided in the energy storage system 1 or may be provided in an upper system of the energy storage system 1.

The energy management system 31b may receive information such as charge information, power usage, and environmental information, and may control the energy storage system 1 according to the energy production, storage, and consumption patterns of user. The energy management system 31b may be provided as an operating system for monitoring and controlling the power management system 31a.

The controller for controlling the overall operation of the energy storage system 1 may include the power management system 31a and/or the energy management system 31b. In some embodiments, one of the power management system 31a and the energy management system 31b may also perform the other function. In addition, the power management system 31a and the energy management system 31b may be integrated into one controller to be integrally provided.

Meanwhile, the installation capacity of the energy storage system 1 varies according to the customer's installation condition, and a plurality of the power conditioning systems 32 and the batteries 35 may be connected to expand to a required capacity.

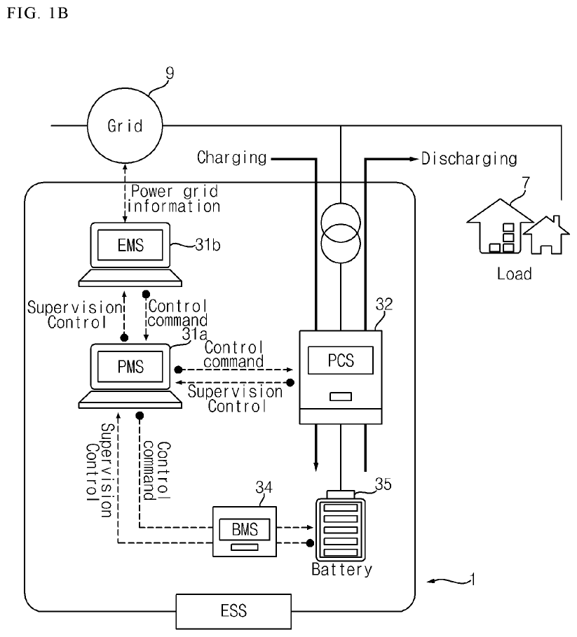

The energy storage system 1 may be connected to at least one generating plant (refer to 3 of FIG. 2) separately from the grid 9. A generating plant 3 may include a wind generating plant that outputs DC power, a hydroelectric generating plant that outputs DC power using hydroelectric power, a tidal generating plant that outputs DC power using tidal power, thermal generating plant that outputs DC power using heat such as geothermal heat, or the like. Hereinafter, for convenience of description, the photovoltaic plant will be mainly described as the generating plant 3.

FIG. 2 is a conceptual diagram of a home energy service system including an energy storage system according to an embodiment of the present disclosure.

The home energy service system according to an embodiment of the present disclosure may include the energy storage system 1, and may be configured as a cloud 5-based intelligent energy service platform for integrated energy service management.

Referring to FIG. 2, the home energy service system is mainly implemented in a home, and may manage the supply, consumption, and storage of energy (power) in the home.

The energy storage system 1 may be connected to a grid 9 such as a power plant 8, a generating plant such as a photovoltaic generator 3, a plurality of loads 7a to 7g, and sensors (not shown) to configure a home energy service system.

The loads 7a to 7g may be a heat pump 7a, a dishwasher 7b, a washing machine 7c, a boiler 7d, an air conditioner 7e, a thermostat 7f, an electric vehicle (EV) charger 7g, a smart lighting 7h, and the like.

The home energy service system may include other loads in addition to the smart devices illustrated in FIG. 2. For example, the home energy service system may include several lights in addition to the smart lighting 7h having one or more communication modules. In addition, the home energy service system may include a home appliance that does not include a communication module.

Some of the loads 7a to 7g are set as essential loads, so that power may be supplied from the energy storage system 1 when a power outage occurs. For example, a refrigerator and at least some lighting devices may be set as essential loads that require backup during power outage.

Meanwhile, the energy storage system 1 can communicate with the devices 7a to 7g, and the sensors through a short-range wireless communication module. For example, the short-range wireless communication module may be at least one of Bluetooth, Wi-Fi, and Zigbee. In addition, the energy storage system 1, the devices 7a to 7g, and the sensors may be connected to an Internet network.

The energy management system 31b may communicate with the energy storage system 1, the devices 7a to 7g, the sensors, and the cloud 5 through an Internet network, and a short-range wireless communication.

The energy management system 31b and/or the cloud 5 may transmit information received from the energy storage system 1, the devices 7a to 7g, and sensors and information determined using the received information to the terminal 6. The terminal 6 may be implemented as a smart phone, a PC, a notebook computer, a tablet PC, or the like. In some embodiments, an application for controlling the operation of the home energy service system may be installed and executed in the terminal 6.

The home energy service system may include a meter 2. The meter 2 may be provided between the power grid 9 such as a power plant 8 and the energy storage system 1. The meter 2 may measure the amount of power supplied to the home from the power plant 8 and consumed. In addition, the meter 2 may be provided inside the energy storage system 1. The meter 2 may measure the amount of power discharged from the energy storage system 1. The amount of power discharged from the energy storage system 1 may include the amount of power supplied (sold) from the energy storage system 1 to the power grid 9, and the amount of power supplied from the energy storage system 1 to the devices 7a to 7g.

The energy storage system 1 may store the power supplied from the photovoltaic generator 2 and/or the power plant 8, or the residual power remaining after the supplied power is consumed.

Meanwhile, the meter 2 may be implemented of a smart meter. The smart meter may include a communication module for transmitting information related to power usage to the cloud 5 and/or the energy management system 31b.

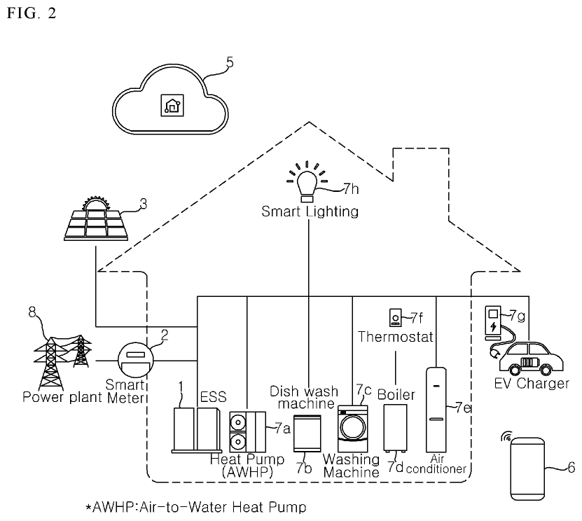

FIGS. 3A and 3B are diagrams illustrating an energy storage system (ESS) installation type according to an embodiment of the present disclosure.

The home energy storage system 1 may be divided into an AC-coupled ESS (see FIG. 3A) and a DC-coupled ESS (see FIG. 3B) according to an installation type.

The photovoltaic plant includes a photovoltaic panel 3. Depending on the type of photovoltaic installation, the photovoltaic plant may include a photovoltaic panel 3 and a photovoltaic (PV) inverter 4 that converts DC power supplied from the photovoltaic panel 3 into AC power (see FIG. 3A). Thus, it is possible to implement the system more economically, as the energy storage system 1 independent of the existing grid 9 can be used.

In addition, according to an embodiment, the power conditioning system 32 of the energy storage system 1 and the PV inverter 4 may be implemented as an integrated power conversion device (see FIG. 3B). In this case, the DC power output from the photovoltaic panel 3 is input to the power conditioning system 32. The DC power may be transmitted to and stored in the battery 35. In addition, the power conditioning system 32 may convert DC power into AC power and supply to the grid 9. Accordingly, a more efficient system implementation can be achieved.

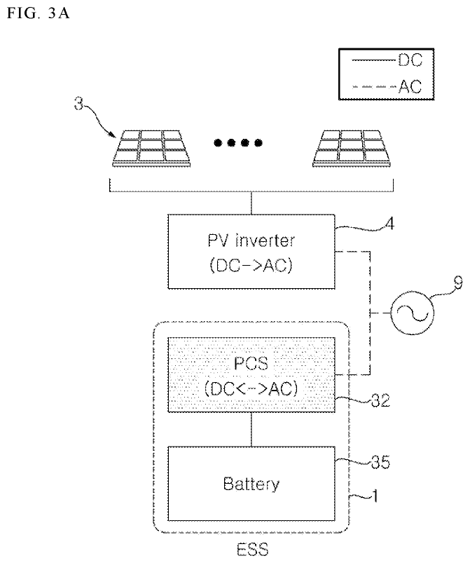

FIG. 4 is a conceptual diagram of a home energy service system including an energy storage system according to an embodiment of the present disclosure.

Referring to FIG. 4, the energy storage system 1 may be connected to the grid 9 such as the power plant 8, the power plant such as the photovoltaic generator 3, and a plurality of loads 7x1 and 7y1.

Electric energy generated by the photovoltaic generator 3 may be converted in the PV inverter 4 and supplied to the grid 9, the energy storage system 1, and the loads 7x1 and 7y1. As described with reference to FIG. 3, according to the type of installation, the electric energy generated by the photovoltaic generator 3 may be converted in the energy storage system 1, and supplied to the grid 9, the energy storage system 1, and the loads 7x1, 7y1.

Meanwhile, the energy storage system 1 is provided with one or more wireless communication modules, and may communicate with the terminal 6. The user may monitor and control the state of the energy storage system 1 and the home energy service system through the terminal 6. In addition, the home energy service system may provide a cloud 5 based service. The user may communicate with the cloud 5 through the terminal 6 regardless of location and monitor and control the state of the home energy service system.

According to an embodiment of the present disclosure, the above-described battery 35, the battery management system 34, and the power conditioning system 32 may be disposed inside one casing 12. Since the battery 35, the battery management system 34, and the power conditioning system 32 integrated in one casing 12 can store and convert power, they may be referred to as an all-in-one energy storage system 1a.

In addition, in a separate enclosure 1b outside the casing 12, a configuration for power distribution such as a power management system 31a, an auto transfer switch (ATS), a smart meter, and a switch, and a communication module for communication with the terminal 6, the cloud 5, and the like may be disposed. A configuration in which a configuration related to power distribution and management is integrated in one enclosure 1 may be referred to as a smart energy box 1b.

The above-described power management system 31a may be received in the smart energy box 1b. A controller for controlling the overall power supply connection of the energy storage system 1 may be disposed in the smart energy box 1b. The controller may be the above mentioned power management system 31a.

In addition, switches are received in the smart energy box 1b to control the connection state of the connected grid power source 8, 9, the photovoltaic generator 3, the battery 35 of all-in-one energy storage system 1a, and loads 7x1, 7y1. The loads 7x1, 7y1 may be connected to the smart energy box 1b through the load panel 7x2, 7y2.

Meanwhile, the smart energy box 1b is connected to the grid power source 8, 9 and the photovoltaic generator 3. In addition, when a power outage occurs in the system 8, 9, the auto transfer switch ATS that is switched so that the electric energy which is generated by the photovoltaic generator 3 or stored in the battery 35 is supplied to a certain load 7y1 may be disposed in the smart energy box 1b.

Alternatively, the power management system 31a may perform an auto transfer switch ATS function. For example, when a power outage occurs in the system 8, 9, the power management system 31a may control a switch such as a relay so that the electric energy that is generated by the photovoltaic generator 3 or stored in the battery 35 is transmitted to a certain load 7y1.

Meanwhile, a current sensor, a smart meter, or the like may be disposed in each current supply path. Electric energy of the electricity generated through the energy storage system 1 and the photovoltaic generator 3 may be measured and managed by a smart meter (at least a current sensor).

The energy storage system 1 according to an embodiment of the present disclosure includes at least an all-in-one energy storage system 1a. In addition, the energy storage system 1 according to an embodiment of the present disclosure includes the all-in-one energy storage system 1a and the smart energy box 1b, thereby providing an integrated service that can simply and efficiently perform storage, supply, distribution, communication, and control of power.

Meanwhile, the energy storage system 1 according to an embodiment of the present disclosure may operate in a plurality of operation modes. In a PV self consumption mode, photovoltaic power generation is first used in the load, and the remaining power is stored in the energy storage system 1. For example, when more power is generated than the amount of power used by the loads 7x1 and 7y1 in the photovoltaic generator 3 during the day, the battery 35 is charged.

In a charge/discharge mode based on a rate system, four time zones may be set and input, the battery 35 may be discharged during a time period when the electric rate is expensive, and the battery 35 may be charged during a time period when the electric rate is cheap. The energy storage system 1 may help a user to save electric rate in the charge/discharge mode based on a rate system.

A backup-only mode is a mode for emergency situations such as power outages, and can operate, with the highest priority, such that when a typhoon is expected by a weather forecast or there is a possibility of other power outages, the battery 35 may be charged up to a maximum and supplied to an essential load 7y1 in an emergency.

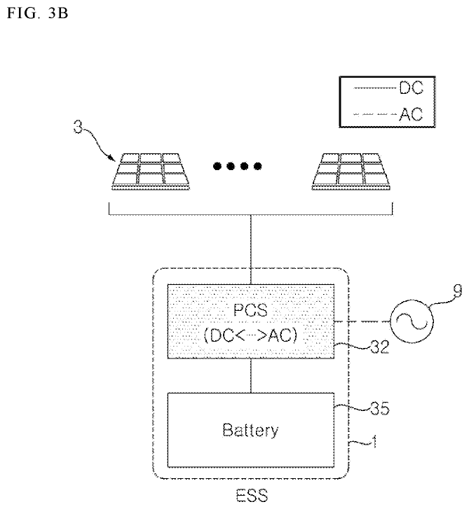

The energy storage system 1 of the present disclosure will be described with reference to FIGS. 5 to 7. More particularly, detailed structures of the all-in-one energy storage system 1a are disclosed.

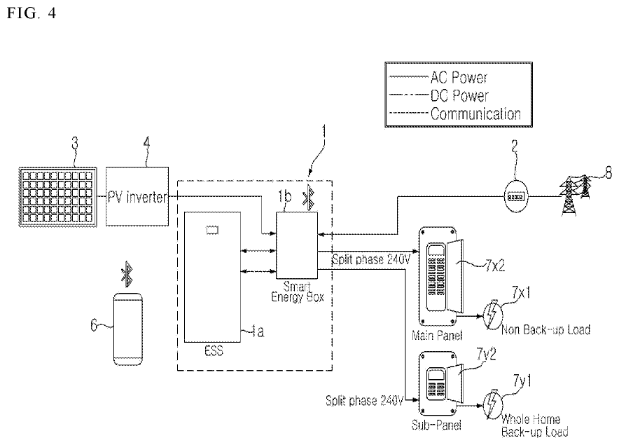

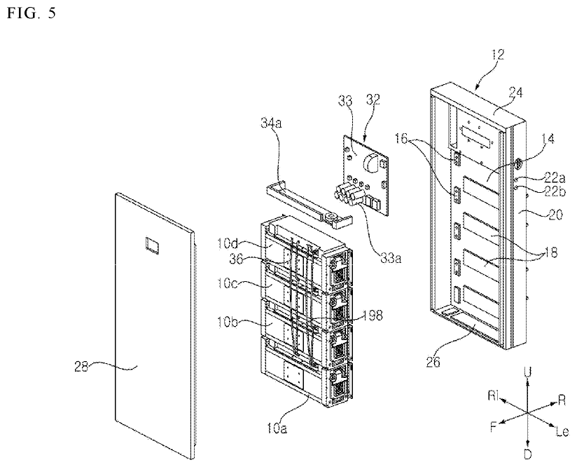

FIG. 5 is an exploded perspective view of an energy storage system including a plurality of battery packs according to an embodiment of the present disclosure, FIG. 6 is a front view of an energy storage system in a state in which a door is removed, FIG. 7 is a cross-sectional view of one side of FIG. 6.

Referring to FIG. 5, the energy storage system 1 includes at least one battery pack 10, a casing 12 forming a space in which at least one battery pack 10 is disposed, a door 28 for opening and closing the front surface of the casing 12, a power conditioning system 32 (PCS) which is disposed inside the casing 12 and converts the characteristics of electricity so as to charge or discharge a battery, and a battery management system (BMS) that monitors information such as current, voltage, and temperature of the battery cell 101.

The casing 12 may have an open front shape. The casing 12 may include a casing rear wall 14 covering the rear, a pair of casing side walls 20 extending to the front from both side ends of the casing rear wall 14, a casing top wall 24 extending to the front from the upper end of the casing rear wall 14, and a casing base 26 extending to the front from the lower end of the casing rear wall 14. The casing rear wall 14 includes a pack fastening portion 16 formed to be fastened with the battery pack 10 and a contact plate 18 protruding to the front to contact the heat dissipation plate 124 of the battery pack 10.

Referring to FIG. 5, the contact plate 18 may be disposed to protrude to the front from the casing rear wall 14. The contact plate 18 may be disposed to contact one side of the heat dissipation plate 124. Accordingly, heat emitted from the plurality of battery cells 101 disposed inside the battery pack 10 may be radiated to the outside through the heat dissipation plate 124 and the contact plate 18.

A switch 22a, 22b for turning on/off the power of the energy storage system 1 may be disposed in one of the pair of casing sidewalls 20. In the present disclosure, a first switch 22a and a second switch 22b are disposed to enhance the safety of the power supply or the safety of the operation of the energy storage system 1.

The power conditioning system 32 may include a circuit substrate 33 and an insulated gate bipolar transistor (IGBT) that is disposed in one side of the circuit substrate 33 and performs power conversion.

The battery monitoring system may include a battery pack circuit substrate 220 disposed in each of the plurality of battery packs 10a, 10b, 10c, 10d, and a main circuit substrate 34a which is disposed inside the casing 12 and connected to a plurality of battery pack circuit substrates 220 through a communication line 36.

The main circuit substrate 34a may be connected to the battery pack circuit substrate 220 disposed in each of the plurality of battery packs 10a, 10b, 10c, and 10d by the communication line 36. The main circuit substrate 34a may be connected to a power line 198 extending from the battery pack 10.

At least one battery pack 10a, 10b, 10c, and 10d may be disposed inside the casing 12. A plurality of battery packs 10a, 10b, 10c, and 10d are disposed inside the casing 12. The plurality of battery packs 10a, 10b, 10c, and 10d may be disposed in the vertical direction.

The plurality of battery packs 10a, 10b, 10c, and 10d may be disposed such that the upper end and lower end of each side bracket 250 contact each other. At this time, each of the battery packs 10a, 10b, 10c, and 10d disposed vertically is disposed such that the battery module 100a, 100b and the top cover 230 do not contact each other.

Each of the plurality of battery packs 10 is fixedly disposed in the casing 12. Each of the plurality of battery packs 10a, 10b, 10c, and 10d is fastened to the pack fastening portion 16 disposed in the casing rear wall 14. That is, the fixing bracket 270 of each of the plurality of battery packs 10a, 10b, 10c, and 10d is fastened to the pack fastening portion 16. The pack fastening portion 16 may be disposed to protrude to the front from the casing rear wall 14 like the contact plate 18.

The contact plate 18 may be disposed to protrude to the front from the casing rear wall 14. Accordingly, the contact plate 18 may be disposed to be in contact with one heat dissipation plate 124 included in the battery pack 10.

One battery pack 10 includes two battery modules 100a and 100b. Accordingly, two heat dissipation plates 124 are disposed in one battery pack 10. One heat dissipation plate 124 included in the battery pack 10 is disposed to face the casing rear wall 14, and the other heat dissipation plate 124 is disposed to face the door 28.

One heat dissipation plate 124 is disposed to contact the contact plate 18 disposed in the casing rear wall 14, and the other heat dissipation plate 124 is disposed to be spaced apart from the door 28. The other heat dissipation plate 124 may be cooled by air flowing inside the casing 12.

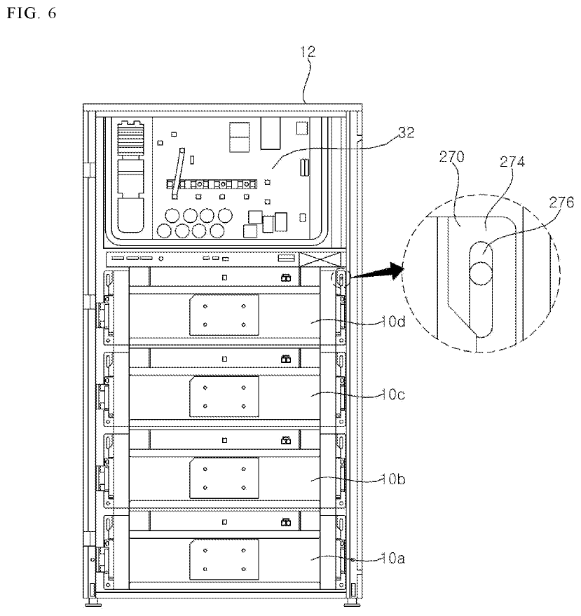

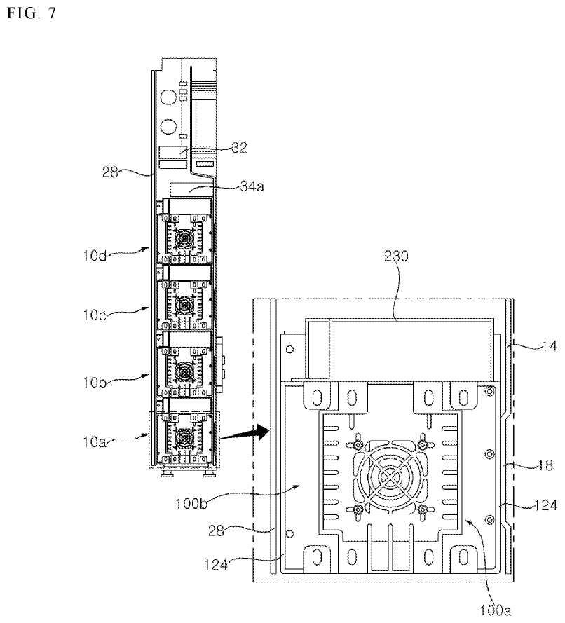

FIG. 8 is a perspective view of a battery pack according to an embodiment of the present disclosure, and FIG. 9 is an exploded view of a battery pack according to an embodiment of the present disclosure.

The energy storage system of the present disclosure may include a battery pack 10 in which a plurality of battery cells 101 are connected in series and in parallel. The energy storage system may include a plurality of battery packs 10a, 10b, 10c, and 10d (refer to FIG. 5).

First, a configuration of one battery pack 10 will be described with reference to FIGS. 8 to 9. The battery pack 10 includes at least one battery module 100a, 100b to which a plurality of battery cells 101 are connected in series and parallel, an upper fixing bracket 200 which is disposed in an upper portion of the battery module 100a, 100b and fixes the disposition of the battery module 100a, 100b, a lower fixing bracket 210 which is disposed in a lower portion of the battery module 100 and fixes the disposition of the battery modules 100a and 100b, a pair of side brackets 250a, 250b which are disposed in both side surfaces of the battery module 100a, 100b and fixes the disposition of the battery module 100a, 100b, a pair of side covers 240a, 240b which are disposed in both side surfaces of the battery module 100a, 100b, and in which a cooling hole 242a is formed, a cooling fan 280 which is disposed in one side surface of the battery module 100a, 100b and forms an air flow inside the battery module 100a, 100b, a battery pack circuit substrate 220 which is disposed in the upper side of the upper fixing bracket 200 and collects sensing information of the battery module 100a, 100b, and a top cover 230 which is disposed in the upper side of the upper fixing bracket 200 and covers the upper side of the battery pack circuit substrate 220.

The battery pack 10 includes at least one battery module 100a, 100b. Referring to FIG. 2, the battery pack 10 of the present disclosure includes a battery module assembly 100 configured of two battery modules 100a, 100b which are electrically connected to each other and physically fixed. The battery module assembly 100 includes a first battery module 100a and a second battery module 100b disposed to face each other.

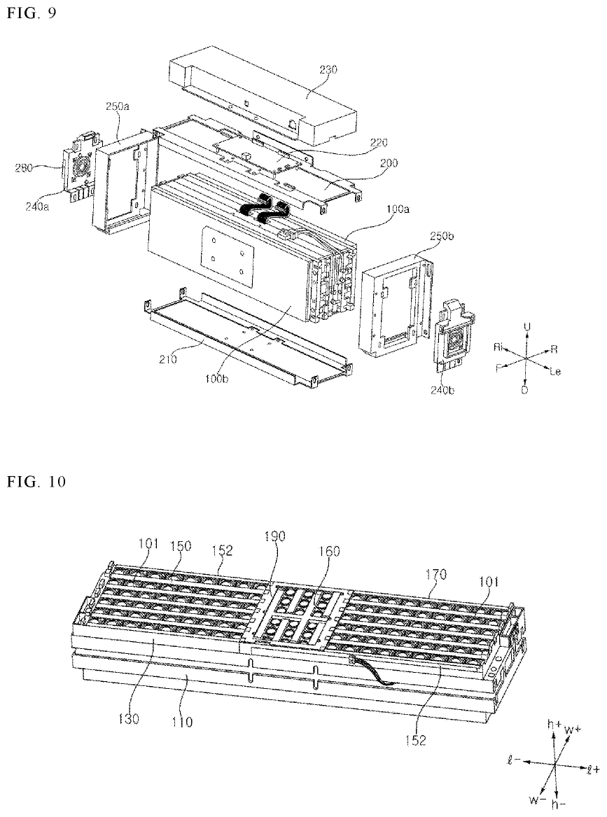

FIG. 10 is a perspective view of a battery module according to an embodiment of the present disclosure and FIG. 11 is an exploded view of a battery module according to an embodiment of the present disclosure.

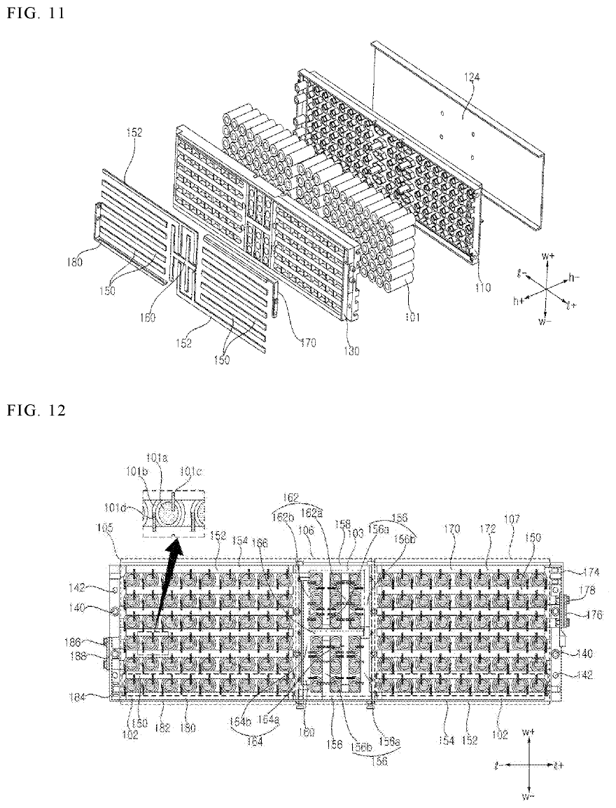

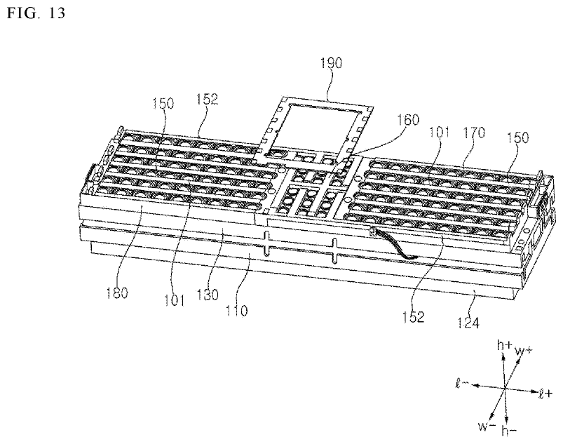

FIG. 12 is a front view of a battery module according to an embodiment of the present disclosure and FIG. 13 is an exploded perspective view of a battery module and a sensing substrate according to an embodiment of the present disclosure. Hereinafter, the first battery module 100a of the present disclosure will be described with reference to FIGS. 10 to 13. The configuration and shape of the first battery module 100a described below may also be applied to the second battery module 100b.

The battery module described in FIGS. 10 to 13 may be described in a vertical direction based on the height direction (h+, h−) of the battery module. The battery module described in FIGS. 10 to 13 may be described in the left-right direction based on the length direction (1+, 1−) of the battery module. The battery module described in FIGS. 10 to 13 may be described in the front-rear direction based on the width direction (w+, w−) of the battery module. The direction setting of the battery module used in FIGS. 10 to 13 may be different from the direction setting in a structure of the battery pack 10 described in other drawings. In the battery module described in FIGS. 10 to 13, the width direction (w+, w−) of the battery module may be described as a first direction, and the length direction (1+, 1−) of the battery module may be described as a second direction.

The first battery module 100a includes a plurality of battery cells 101, a first frame 110 for fixing the lower portion of the plurality of battery cells 101, a second frame 130 for fixing the upper portion of the plurality of battery cells 101, a heat dissipation plate 124 which is disposed in the lower side of the first frame 110 and dissipates heat generated from the battery cell 101, a plurality of bus bars which are disposed in the upper side of the second frame 130 and electrically connect the plurality of battery cells 101, and a sensing substrate 190 which is disposed in the upper side of the second frame 130 and detects information of the plurality of battery cells 101.

The first frame 110 and the second frame 130 may fix the disposition of the plurality of battery cells 101. In the first frame 110 and the second frame 130, the plurality of battery cells 101 are disposed to be spaced apart from each other. Since the plurality of battery cells 101 are spaced apart from each other, air may flow into a space between the plurality of battery cells 101 by the operation of the cooling fan 280 described below.

The first frame 110 fixes the lower end of the battery cell 101. The first frame 110 includes a lower plate 112 having a plurality of battery cell holes 112a formed therein, a first fixing protrusion 114 which protrudes upward from the upper surface of the lower plate 112 and fixes the disposition of the battery cell 101, a pair of first sidewalls 116 which protrudes upward from both ends of the lower plate 112, and a pair of first end walls 118 which protrudes upward from both ends of the lower plate 112 and connects both ends of the pair of first side walls 116.

The pair of first sidewalls 116 may be disposed parallel to a first cell array 102 described below. The pair of first end walls 118 may be disposed perpendicular to the pair of first side walls 116.

Referring to FIG. 13, the first frame 110 includes a first fastening protrusion 120 protruding to be fastened to the second frame 130, and a module fastening protrusion 122 protruding to be fastened with the first frame 110 included in the second battery module 100b disposed adjacently. A frame screw 125 for fastening the second frame 130 and the first frame 110 is disposed in the first fastening protrusion 120. A module screw 194 for fastening the first battery module 100a and the second battery module 100b is disposed in the module fastening protrusion 122. The frame screw 125 fastens the second frame 130 and the first frame 110.

The frame screw 125 may fix the disposition of the plurality of battery cells 101 by fastening the second frame 130 and the first frame 110.

The plurality of battery cells 101 are fixedly disposed in the second frame 130 and the first frame 110. A plurality of battery cells 101 are disposed in series and parallel. The plurality of battery cells 101 are fixedly disposed by a first fixing protrusion 114 of the first frame 110 and a second fixing protrusion 134 of the second frame 130.

Referring to FIG. 12, the plurality of battery cells 101 are spaced apart from each other in the length direction (1+, 1−) and the width direction (w+, w−) of the battery module.

The plurality of battery cells 101 includes a cell array connected in parallel to one bus bar. The cell array may refer to a set electrically connected in parallel to one bus bar.

The first battery module 100a may include a plurality of cell arrays 102 and 103 electrically connected in series. The plurality of cell arrays 102 and 103 are electrically connected to each other in series. The first battery module 100a has a plurality of cell arrays 102 and 103 connected in series.

The plurality of cell arrays 102 and 103 may include a first cell array 102 in which a plurality of battery cells 101 are disposed in a straight line, and a second cell array 103 in which a plurality of cell array rows and columns are disposed.

The first battery module 100a may include a first cell array 102 in which a plurality of battery cells 101 are disposed in a straight line, and a second cell array 103 in which a plurality of rows and columns are disposed.

Referring to FIG. 12, in the first cell array 102, a plurality of battery cells 101 are disposed in the left and right side in the length direction (1+, 1−) of the first battery module 100a. The plurality of first cell arrays 102 are disposed in the front and rear side in the width direction (w+, w−) of the first battery module 100a.

Referring to FIG. 12, the second cell array 103 includes a plurality of battery cells 101 spaced apart from each other in the width direction (w+, w−) and the length direction (1+, 1−) of the first battery module 100a.

The first battery module 100a includes a first cell group 105 in which a plurality of first cell arrays 102 are disposed in parallel, and a second cell group 106 that includes at least one second cell array 103 and is disposed in one side of the first cell group 105.

The first battery module 100a includes a first cell group 105 in which a plurality of first cell arrays 102 are connected in series, and a third cell group 107 in which a plurality of first cell arrays 102 are connected in series, and which are spaced apart from the first cell group 105. The second cell group is disposed between the first cell group 105 and the third cell group 107.

In the first cell group 105, a plurality of first cell arrays 102 are connected in series. In the first cell group 105, a plurality of first cell arrays 102 are spaced apart from each other in the width direction of the battery module. The plurality of first cell arrays 102 included in the first cell group 105 are spaced apart in a direction perpendicular to the direction in which the plurality of battery cells 101 included in each of the first cell arrays 102 are disposed.

Referring to FIG. 12, nine battery cells 101 connected in parallel are disposed in each of the first cell array 102 and the second cell array 103. Referring to FIG. 12, in the first cell array 102, nine battery cells 101 are spaced apart from each other in the length direction of the battery module. In the second cell array 103, nine battery cells are spaced apart from each other in a plurality of rows and a plurality of columns. Referring to FIG. 12, in the second cell array 103, three battery cells 101 that are spaced apart from each other in the width direction of the battery module are spaced apart from each other in the length direction of the battery module. Here, the length direction (1+, 1−) of the battery module may be set as a column direction, and the width direction (w+, w−) of the battery module may be set as a row direction.

Referring to FIG. 12, each of the first cell group 105 and the third cell group 107 is disposed such that six first cell arrays 102 are connected in series. In each of the first cell group 105 and the third cell group 107, six first cell arrays 102 are spaced apart from each other in the width direction of the battery module.

Referring to FIG. 12, the second cell group 106 includes two second cell arrays 103. The two second cell arrays 103 are spaced apart from each other in the width direction of the battery module. The two second cell arrays 103 are connected in parallel to each other. Each of the two second cell arrays 103 is disposed symmetrically with respect to the horizontal bar 166 of a third bus bar 160 described below.

The first battery module 100a includes a plurality of bus bars which are disposed between the plurality of battery cells 101, and electrically connect the plurality of battery cells 101. Each of the plurality of bus bars connects in parallel the plurality of battery cells included in a cell array disposed adjacent to each other. Each of the plurality of bus bars may connect in series two cell arrays disposed adjacent to each other.

The plurality of bus bars includes a first bus bar 150 connecting the two first cell arrays 102 in series, a second bus bar 152 connecting the first cell array 102 and the second cell array 103 in series, and a third bus bar 160 connecting the two second cell arrays 103 in series.

The plurality of bus bars include a fourth bus bar 170 connected to one first cell array 102 in series. The plurality of bus bars include a fourth bus bar 170 which is connected to one first cell array 102 in series and connected to other battery module 100b included in the same battery pack 10, and a fifth bus bar 180 which is connected to one first cell array 102 in series and connected to one battery module included in other battery pack 10. The fourth bus bar 170 and the fifth bus bar 180 may have the same shape.

The first bus bar 150 is disposed between two first cell arrays 102 spaced apart from each other in the length direction of the battery module. The first bus bar 150 connects in parallel a plurality of battery cells 101 included in one first cell array 102. The first bus bar 150 connects in series the two first cell arrays 102 disposed in the length direction (1+, 1−) of the battery module.

Referring to FIG. 12, it is electrically connected to a positive terminal 101a of each of the battery cells 101 of the first cell array 102 which is disposed in the front in the width direction (w+, w−) of the battery module with respect to the first bus bar 150, and is electrically connected to a negative terminal 101b of each of the battery cells 101 of the first cell array 102 which is disposed in the rear in the width direction (w+, w−) of the battery module with respect to the first bus bar 150.

Referring to FIG. 12, in the battery cell 101, the positive terminal 101a and the negative terminal 101b are partitioned in the upper end thereof. In the battery cell 101, the positive terminal 101a is disposed in the center of a top surface formed in a circle, and the negative terminal 101b is disposed in the circumference portion of the positive terminal 101a. Each of the plurality of battery cells 101 may be connected to each of the plurality of bus bars through a cell connector 101c, 101d.

The first bus bar 150 has a straight bar shape. The first bus bar 150 is disposed between the two first cell arrays 102. The first bus bar 150 is connected to the positive terminal of the plurality of battery cells 101 included in the first cell array 102 disposed in one side, and is connected to the negative terminal of the plurality of battery cells 101 included in the first cell array 102 disposed in the other side.

The first bus bar 150 is disposed between the plurality of first cell arrays 102 disposed in the first cell group 105 and the third cell group 107.

The second bus bar 152 connects the first cell array 102 and the second cell array 103 in series. The second bus bar 152 includes a first connecting bar 154 connected to the first cell array 102 and a second connecting bar 156 connected to the second cell array 103. The second bus bar 152 is disposed perpendicular to the first connecting bar 154. The second bus bar 152 includes an extension portion 158 that extends from the first connecting bar 154 and is connected to the second connecting bar 156.

The first connecting bar 154 may be connected to different electrode terminals of the second connecting bar 156 and the battery cell. Referring to FIG. 12, the first connecting bar 154 is connected to the positive terminal 101a of the battery cell 101 included in the first cell array 102, and the second connecting bar 156 is connected to the negative terminal 101b of the battery cell 101 included in the second cell array 103. However, this is just an embodiment and it is possible to be connected to opposite electrode terminal.

The first connecting bar 154 is disposed in one side of the first cell array 102. The first connecting bar 154 has a straight bar shape extending in the length direction of the battery module. The extension portion 158 has a straight bar shape extending in the direction in which the first connecting bar 154 extends.

The second connecting bar 156 is disposed perpendicular to the first connecting bar 154. The second connecting bar 156 has a straight bar shape extending in the width direction (w+, w−) of the battery module. The second connecting bar 156 may be disposed in one side of the plurality of battery cells 101 included in the second cell array 103. The second connecting bar 156 may be disposed between the plurality of battery cells 101 included in the second cell array 103. The second connecting bar 156 extends in the width direction (w+, w−) of the battery module, and is connected to the battery cell 101 disposed in one side or both sides.

The second connecting bar 156 includes a second-first connecting bar 156a and a second-second connecting bar 156b spaced apart from the second-first connecting bar 156a. The second-first connecting bar 156a is disposed between the plurality of battery cells 101, and the second-second connecting bar 156b is disposed in one side of the plurality of battery cells 101.

The third bus bar 160 connects in series the two second cell arrays 103 spaced apart from each other. The third bus bar 160 includes a first vertical bar 162 connected to one cell array among the plurality of second cell arrays 103, a second vertical bar 164 connected to the other cell array among the plurality of second cell arrays 103, and a horizontal bar 166 which is disposed between the plurality of second cell arrays 103 and connected to the first vertical bar 162 and the second vertical bar 164. The first vertical bar 162 and the second vertical bar 164 may be symmetrically disposed with respect to the horizontal bar 166.

A plurality of second vertical bars 164 may be disposed to be spaced apart from each other in the length direction (1+, 1−) of the battery module. Referring to FIG. 12, a second-first vertical bar 164a, and a second-second vertical bar 164b which is spaced apart from the second-first vertical bar 164a in the length direction of the battery module may be included.

The first vertical bar 162 or the second vertical bar 164 may be disposed parallel to the second connecting bar 156 of the second bus bar 152. The battery cell 101 included in the second cell array 103 may be disposed between the first vertical bar 162 and the second connecting bar 156. Similarly, the battery cell 101 included in the second cell array 103 may be disposed between the second vertical bar 164 and the second connecting bar 156.

The first battery module 100a includes a fourth bus bar 170 connected to the second battery module 100b included in the same battery pack 10, and a fifth bus bar 180 connected to one battery module included in other battery pack 10.

The fourth bus bar 170 is connected to the second battery module 100b which is another battery module included in the same battery pack 10. That is, the fourth bus bar 170 is connected to the second battery module 100b included in the same battery pack 10 through a high current bus bar 196 described below.

The fifth bus bar 180 is connected to other battery pack 10. That is, the fifth bus bar 180 may be connected to a battery module included in other battery pack 10 through a power line 198 described below.

The fourth bus bar 170 includes a cell connecting bar 172 which is disposed in one side of the first cell array 102, and connects in parallel the plurality of battery cells 101 included in the first cell array 102, and an additional connecting bar 174 which is vertically bent from the cell connecting bar 172 and extends along the end wall of the second frame 130.

The cell connecting bar 172 is disposed in the second sidewall 136 of the second frame 130. The cell connecting bar 172 may be disposed to surround a portion of the outer circumference of the second sidewall 136. The additional connecting bar 174 is disposed outside the second end wall 138 of the second frame 130.

The additional connecting bar 174 includes a connecting hanger 176 to which the high current bus bar 196 is connected. The connecting hanger 176 is provided with a groove 178 opened upward. The high current bus bar 196 may be seated on the connecting hanger 176 through the groove 178. The high current bus bar 196 may be fixedly disposed in the connecting hanger 176 through a separate fastening screw while seated on the connecting hanger 176.

The fifth bus bar 180 may have the same configuration and shape as the fourth bus bar. That is, the fifth bus bar 180 includes a cell connecting bar 182 and an additional connecting bar 184. The additional connecting bar 184 of the fifth bus bar 180 includes a connecting hanger 186 to which a terminal 198a of the power line 198 is connected. The connecting hanger 186 is provided with a groove 188 into which the terminal 198a of the power line 198 is inserted.

The sensing substrate 190 is electrically connected to a plurality of bus bars disposed inside the first battery module 100a. The sensing substrate 190 may be electrically connected to each of the plurality of first bus bars 150, the plurality of second bus bars 152, the third bus bar 160, and the plurality of fourth bus bars 170, respectively. The sensing substrate 190 is connected to each of the plurality of bus bars, so that information such as voltage and current values of the plurality of battery cells 101 included in the plurality of cell arrays can be obtained.

The sensing substrate 190 may have a rectangular ring shape. The sensing substrate 190 may be disposed between the first cell group 105 and the third cell group 107. The sensing substrate 190 may be disposed to surround the second cell group 106. The sensing substrate 190 may be disposed to partially overlap the second bus bar 152.

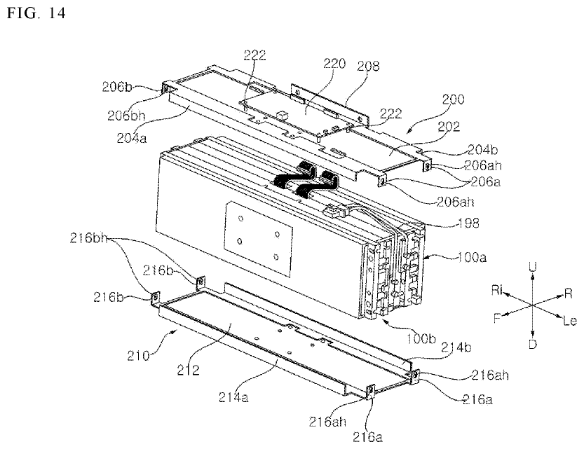

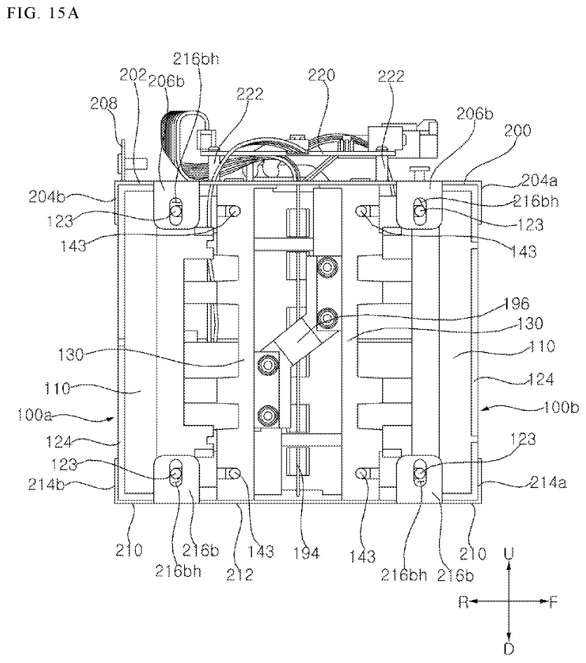

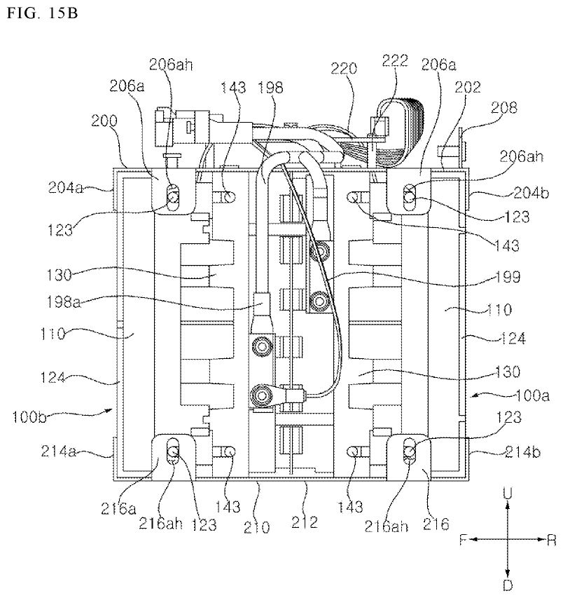

FIG. 14 is a perspective of a battery module and a battery pack circuit substrate according to an embodiment of the present disclosure, FIG. 15A is one side view in a coupled state of FIG. 14, and FIG. 15B is the other side view in a coupled state of FIG. 14.

Referring to FIGS. 14 to 15B, the battery pack 10 includes an upper fixing bracket 200 which is disposed in an upper portion of the battery module 100a, 100b and fixes the battery module 100a, 100b, a lower fixing bracket 210 which is disposed in a lower portion of the battery module 100 and fixes the battery modules 100a and 100b, a battery pack circuit substrate 220 which is disposed in an upper side of the upper fixing bracket 200 and collects sensing information of the battery module 100a, 100b, and a spacer 222 which separates the battery pack circuit substrate 220 from the upper fixing bracket 200.

The upper fixing bracket 200 is disposed in an upper side of the battery module 100a, 100b. The upper fixing bracket 200 includes an upper board 202 that covers at least a portion of the upper side of the battery module 100a, 100b, a first upper holder 204a which is bent downward from the front end of the upper board 202 and disposed in contact with the front portion of the battery module 100a, 100b, a second upper holder 204b which is bent downward from the rear end of the upper board 202 and disposed in contact with the rear portion of the battery module 100a, 100b, a first upper mounter 206a which is bent downward from one side end of the upper board 202 and coupled to one side of the battery module 100a, 100b, a second upper mounter 206b which is bent downward from the other side end of the upper board 202 and coupled to the other side of the battery module 100a, 100b, and a rear bender 208 which is bent upward from the rear end of the upper board 202.

The upper board 202 is disposed in the upper side of the battery module 100a, 100b. Each of the first upper mounter 206a and the second upper mounter 206b is disposed to surround the front and rear of the battery module 100a, 100b. Accordingly, the first upper mounter 206a and the second upper mounter 206b may maintain a state in which the first battery module 100a and the second battery module 100b are coupled.

A pair of first upper mounters 206a spaced apart in the front-rear direction are disposed in one side end of the upper board 202. A pair of second upper mounters 206b spaced apart in the front-rear direction are disposed in the other side end of the upper board 202.

The pair of first upper mounters 206a are coupled to the first fastening hole 123 formed in the first battery module 100a and the second battery module 100b. In each of the pair of first upper mounters 206a, a first upper mounter hole 206ah is formed in a position corresponding to the first fastening hole 123. Similarly, the pair of second upper mounters 206b are coupled to the first fastening hole 123 formed in the first battery module 100a and the second battery module 100b, and a second upper mounter hole 206bh is formed in a position corresponding to the first fastening hole 123.

The position of the upper fixing bracket 200 can be fixed in the upper side of the battery module 100a, 100b by the first upper holder 204a, the second upper holder 204b, the first upper mounter 206a, and the second upper mounter 206b. That is, due to the above structure, the upper fixing bracket 200 can maintain the structure of the battery module 100a, 100b.

The upper fixing bracket 200 is fixed to the first frame 110 of each of the first battery module 100a and the second battery module 100b. Each of the first upper mounter 206a and the second upper mounter 206b of the upper fixing bracket 200 is fixed to the first fastening hole 123 formed in the first frame 110 of each of the first battery module 100a and the second battery module 100b.

The rear bender 208 may fix a top cover 230 described below. The rear bender 208 may be fixed to a rear wall 234 of the top cover 230. The rear bender 208 may limit the rear movement of the top cover 230. Accordingly, it is possible to facilitate fastening of the top cover 230 and the upper fixing bracket 200.

The lower fixing bracket 210 is disposed in the lower side of the battery module 100a, 100b. The lower fixing bracket 210 includes a lower board 212 that covers at least a portion of the lower portion of the battery module 100a, 100b, a first lower holder 214a which is bent upward from the front end of the lower board 212 and disposed in contact with the front portion of the battery module 100a, 100b, a second lower holder 214b which is bent upward from the rear end of the lower board 212 and disposed in contact with the rear portion of the battery module 100a, 100b, a first lower mounter 216a which is bent upward from one side end of the lower board 212 and coupled to one side of the battery module 100a, 100b, and a second lower mounter 216b which is bent upward from the other side end of the lower board 212 and coupled to the other side of the battery module 100.

Each of the first lower mounter 216a and the second lower mounter 216b is disposed to surround the front and rear of the battery module 100a, 100b. Accordingly, the first lower mounter 216a and the second lower mounter 216b may maintain the state in which the first battery module 100a and the second battery module 100b are coupled.

A pair of first lower mounters 216a spaced apart in the front-rear direction are disposed in one side end of the lower board 212. A pair of second lower mounters 216b spaced apart in the front-rear direction are disposed in the other side end of the lower board 212.

The pair of first lower mounters 216a are coupled to the first fastening hole 123 formed in the first battery module 100a and the second battery module 100b. In each of the pair of first lower mounters 216a, a first lower mounter hole 216ah is formed in a position corresponding to the first fastening hole 123. Similarly, the pair of second lower mounters 216b are coupled to the first fastening hole 123 formed in the first battery module 100a and the second battery module 100b, and a second lower mounter hole 216bh is formed in a position corresponding to the first fastening hole 123.

The lower fixing bracket 210 is fixed to the first frame 110 of each of the first battery module 100a and the second battery module 100b. Each of the first lower mounter 216a and the second lower mounter 216b of the lower fixing bracket 210 is fixed to the first fastening hole 123 formed in the first frame 110 of each of the first battery module 100a and the second battery module 100b.

The battery pack circuit substrate 220 may be fixedly disposed in the upper side of the upper fixing bracket 200. The battery pack circuit substrate 220 is connected to the sensing substrate 190, the bus bar, or a thermistor 224 described below to receive information of a plurality of battery cells 101 disposed inside the battery pack 10. The battery pack circuit substrate 220 may transmit information of the plurality of battery cells 101 to the main circuit substrate 34a described below.

The battery pack circuit substrate 220 may be spaced apart from the upper fixing bracket 200 upward. A plurality of spacers 222 are disposed, between the battery pack circuit substrate 220 and the upper fixing bracket 200, to space the battery pack circuit substrate 220 upward from the upper fixing bracket 200. The plurality of spacers 222 may be disposed in an edge portion of the battery pack circuit substrate 220.

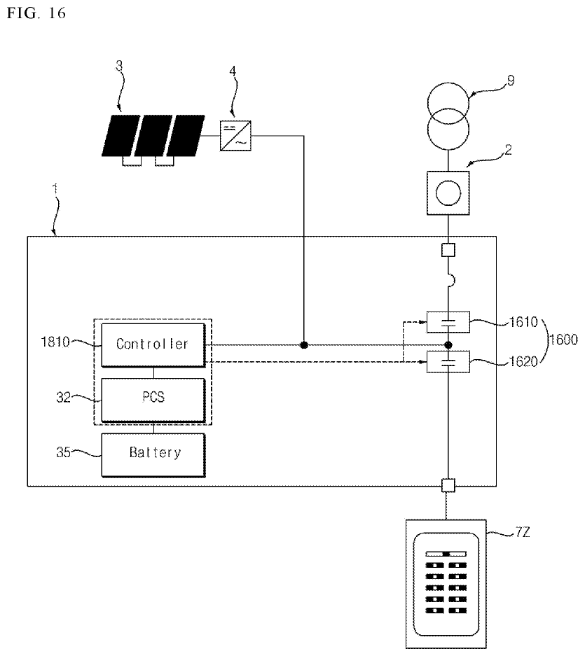

FIG. 16 is a conceptual diagram of an energy supplying system including an energy storage system according to an embodiment of the present disclosure.

Referring to FIG. 16, the energy storage system 1 according to an embodiment of the present disclosure is connected to the grid 9 and a photovoltaic panel 3.

As described with reference to FIG. 3A, the DC power generated by the photovoltaic panel 3 may be converted into AC power in a photovoltaic (PV) inverter 4.

A meter 2 may be provided between the power grid 9, such as the power plant 8, and the energy storage system 1. The meter 2 may measure the amount of power that is supplied through the grid and consumed.

The energy storage system 1 includes a battery 35 that stores the electric energy received from the grid 9 or the photovoltaic panel 3 in a DC form, or outputs the stored electric energy to one or more loads.

As described with reference to FIGS. 1 to 15B, the battery 35 includes a plurality of battery packs 10, and the power input/output during charging/discharging of the battery 35 may be converted in the power conditioning system 32. For example, when charging the battery 35, the power conditioning system 32 may convert AC power received from the grid 9 or the photovoltaic panel 3 into DC power. When discharging the battery 35, the power conditioning system 32 may convert the DC power stored in the battery 35 into AC power.

Meanwhile, the load 7 may be connected to the energy storage system 1 through one or more load panels 7Z. According to an embodiment of the present disclosure, the energy storage system 1 includes a plurality of relays 1600 or switches, and may control the connection relationship of the grid 9, the photovoltaic panel 3, the battery 35, and the load 7.

The relay 1600 includes a grid relay 1610 disposed in a power path connected to the grid 9 and a load relay 1620 capable of connecting or blocking a power path connected to the load 7.

When the grid relay 1610 is turned on, a power path between the grid 9 and the energy storage system 1 is connected. Accordingly, the grid 9 may be connected to the photovoltaic panel 3, the battery 35, and the load 7 through the energy storage system 1. When the grid relay 1610 is turned off, the power path between the grid 9 and the energy storage system 1 is blocked.

When the load relay 1620 is turned on, a power path between the load 7 and the energy storage system 1 is connected. Accordingly, the load 7 may be connected to the grid 9, the photovoltaic panel 3, and the battery 35 through the energy storage system 1. When the load relay 1620 is turned off, the power path between the load 7 and the energy storage system 1 is blocked.

When an error such as a power outage occurs in the grid 9, the grid relay 1610 is turned off to block the power path on the grid 9 side.

Meanwhile, the load relay 1620 maintains a turn-on state, and electric energy generated by the photovoltaic panel 3 or stored in the battery 35 is supplied to a preset load.

In normal times, the grid 9, the photovoltaic panel 3, and the battery 35 are all connected to the load 7, and power supply to the load 7 may be controlled based on at least one of the required electric power of the load 7, the electricity rate of the grid 9, the power generation amount of the photovoltaic panel 3, and the state of charge of the battery 35.

However, when an error such as a power outage occurs in the grid 9, the grid relay 1610 power path is blocked to block the grid 9 from the energy storage system 1. Accordingly, the photovoltaic panel 3 and the battery 35 are separated from the grid 9, and the energy storage system 1 and the load 7 can be protected from overcurrent generated in the grid 9.

Meanwhile, load panel 7Z may correspond to one or more of load panel 7y2 and load panel 7x2 of FIG. 4. That is, the essential load to which power is supplied during a power outage illustrated in FIG. 16 and the load panel 7Z connected to the essential load may correspond to the load 7y1 and the load panel 7y2 of FIG. 4. The essential load to which power is supplied even during a power outage may be previously set and connected to the load panel 7y2. A general load to which power is not supplied during a power outage may be connected to other load panel 7x2.

As described with reference to FIGS. 1 to 15B, the energy storage system 1 includes the power conditioning system 32 and the battery management system 34.

The battery 35, the power conditioning system 32, and the battery management system 34 may be accommodated in one casing 12.

Meanwhile, a power management system 31a for controlling the power conditioning system 32 may be further included, and the power management system 31a may be disposed in the enclosure 1b separate from the casing 12.

According to an embodiment of the present disclosure, the grid relay 1610 and the load relay 1620 may also be disposed in the enclosure 1b.

The power management system 31a may control the relay 1600. When an error occurs in the grid power supply, the power management system 31a may control the grid relay 1610 and the load relay 1620 so that the electric energy generated on the photovoltaic panel 3 or stored in the battery 35 is supplied to a preset essential load 7y2.

A controller 1810 for controlling the overall power supply connection of the energy storage system 1 may be disposed in the enclosure 1b. In addition, the controller 1810 may control the power conditioning system 32, and the like. In some cases, the controller 1810 may be the power management system 31a.

When an error occurs in the grid power supply, the controller 1810 may control the grid relay 1610 and the load relay 1620 so that the electric energy generated on the photovoltaic panel 3 or stored in the battery 35 is supplied to a preset essential load 7y2.

Meanwhile, the controller 1810 turns off the load relay 1620, when the state of charge (SOC) of the battery 35 is lower than a preset off-reference value.

The controller 1810 may calculate the state of charge of the battery 35 by using various well-known methods for calculating the state of charge (SOC). Alternatively, the battery management system 34 may determine the state of charge of the battery 35 and transmit to the controller 1810.

In a case where a power outage occurs and an emergency power generation operation is performed, when the state of charge of the battery 35 falls below a preset specific value-off-reference value as use time is elapsed, the controller 1810 controls the load relay 1620 to block the power path connected to the essential load 7y2.

In some embodiment, after the grid relay 1610 is turned off and a certain time has elapsed, when the state of charge of the battery 35 is lower than the off-reference value, the load relay 1620 may be turned off.

The off-reference value may be set to be higher than the minimum state of charge in which the battery 35 is deteriorated and cannot be recovered. For example, when the minimum state of charge is 5%, the off-reference value may be set at a level of 10 to 15% by securing a certain margin. Accordingly, it is possible to prevent a situation in which the battery 35 becomes unusable as a lower limit of the safe use capacity (e.g., 5%) of the battery 35 is reached. Meanwhile, if the off-reference value is set too high by increasing the margin range, the efficiency of using the battery 35 decreases, and if the off-reference value is set too low by decreasing the margin range, it approaches the lower limit of the safe use capacity to increase a risk.

When the photovoltaic panel 3 produces power, while being separated from the grid 9 due to a power outage, the power generated from the photovoltaic panel may be used to charge the battery 3.

When the state of charge of the battery 35 becomes higher than the off-reference value due to charging, the controller 1810 may control the load relay 1820 to be turned on. Accordingly, the power stored in the battery 35 or the power generated by the photovoltaic panel 3 may be supplied to the essential load 7y1 again.

Alternatively, when the state of charge of the battery 35 is higher than an on-reference value set higher than the off-reference value, the controller 1810 may control the load relay 1820 to be turned on. Accordingly, a decrease in efficiency due to frequent on/off of the load relay 1820 may be prevented.

Photovoltaic power generation can be accomplished only during the day when there is sunlight, and it is affected by environmental conditions such as cloud and rain. In addition, even when the control signal of the PV inverter 4 or the power supply is abnormal, photovoltaic power generation cannot be performed.

In a state of being separated from the grid 9 due to a power outage, if no power is generated from the photovoltaic panel, the controller 1810 may control to enter a power save mode that performs only a preset minimum operation. For example, in the power save mode, functions excluding essential functions are stopped, power is supplied only to essential components, and the switching operation of the power conditioning system 32 can be minimized.

According to an embodiment of the present disclosure, when the state of charge of battery falls below a specific value (off-reference value) due to an emergency power generation mode (Backup Mode) using the battery 35 during a power outage, the load relay 1620 is turned off.

Meanwhile, the controller 1810 may automatically generate a photovoltaic inverter driving signal (e.g., a reference voltage) so that the PV inverter 4 can operate again in the power save mode. The photovoltaic inverter driving signal may include system parameters, such as voltage and frequency, necessary for controlling the inverter. For example, the photovoltaic inverter driving signal may be a signal corresponding to a reference voltage when the power of the grid 9 is in a normal state.

The reference voltage may be a grid voltage supplied by a commercial power grid, etc. in a normal state (when no power outage). Usually, the PV inverter 4 operates based on the grid voltage for safety and efficiency. The PV inverter 4 checks the grid voltage and converts the power according to the grid 9. For example, the photovoltaic inverter 4 may generate a current command value based on the reference voltage, generate a PWM inverter control signal according to the current command value, and perform a switching operation for power conversion.

When the energy storage system 1 coupled with the photovoltaic panel 3 operates as an emergency power generation operation during a power outage, if the power outage is prolonged for one day or more, the energy stored in the battery 35 may be consumed. Accordingly, sufficient power may not be supplied to the load 7y1. In addition, even if sunlight exists, the photovoltaic generator 3 and 4 may not operate normally, or the photovoltaic power generation itself may become impossible.

According to an embodiment of the present disclosure, even though the energy stored in the storage battery 35 is consumed due to a power outage, it is possible to build a system which enables an emergency power generation operation that can stably use power by recharging the battery 35 so long as sunlight exists.

In a case where power generation is possible through the photovoltaic panel 3, the controller 1810 may first charge the storage battery 35 with the power generated by the photovoltaic panel 3, and control to continue a corresponding operation until the state of charge of battery rises to a specific value (off-reference value or on-reference value) or more.

According to the embodiments of the present disclosure, when the state of charge of battery rises to a specific value or more, the controller 1810 controls the load relay 1620 to reconnect the power path connected to the load 7y1, thereby supplying power to the load 7y1.

If sunlight does not exist (due to night, or the influence of weather) to disable photovoltaic power generation, the ESS system enters the power save mode which is the minimum power consumption mode.

Operating method: When it is a time, which is previously set through a timer, when there is a high probability that sunlight exists, a reference voltage is automatically generated to check whether electricity is generated by photovoltaic power generation, and if electricity is generated, it is charged to the battery. If power is not generated, a corresponding operation is attempted several times after a preset period time and it is checked whether power is generated by photovoltaic power generation. Even though the operation of checking whether power is generated by photovoltaic power generation for a preset number of times is performed, if power is not generated by photovoltaic power generation, the energy storage system 1 enters a power save mode in which essential components consumes only minimum power, and remains in the same state until further notice.

According to embodiments of the present disclosure, as a device for determining the presence or absence of sunlight, a timing-based software operation algorithm, an illuminance sensor 1800, or a physical handling switch 2100 may be used.

For example, in the power save mode state, when a preset setting time is reached, the controller 1810 may control to transmit the photovoltaic inverter driving signal to the photovoltaic inverter 4 that converts the power generated by the photovoltaic panel 3.

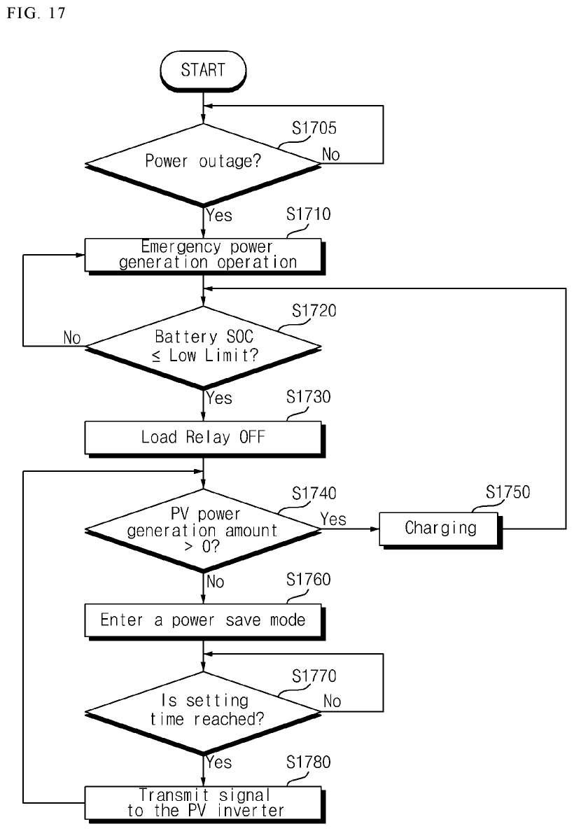

FIG. 17 is a flowchart of a method of operating an energy storage system according to an embodiment of the present disclosure. FIG. 17 illustrates a method for controlling the battery 35 to be charged in the event of a power outage by utilizing the load relay 1620 that controls the load power path.

When a power outage occurs (S1705), the controller 1810 controls the grid relay 1610 so that the energy storage system 1 switches to the emergency power generation operation mode and operates (S1710). That is, when a transition occurs (S1705), the connection with the grid distribution 9 is blocked, and an independent distribution is configured, thereby configuring a system that can use the photovoltaic power generation 3 and the energy storage system 1 power.

In the emergency power generation operation mode, the controller 1810 monitors whether the state of charge of battery falls to a preset low limit or less (S1720). The preset lower limit may be the above-described off-reference value.

Meanwhile, when the state of charge of battery falls to a preset low limit or less (S1720), the controller 1810 may turn off the load relay 162 (S1730).

When the amount of power generated by the photovoltaic panel 3 exists in the state in which the load relay 162 is turned off (S1740), the battery 35 is charged with the power generated by the photovoltaic panel 3 (S1750).

When the amount of power generated by the photovoltaic panel 3 is zero (S1740), the controller 1810 may control the energy storage system 1 to enter a power save mode (S1760).

Conventionally, when a power outage occurs, the PV inverter 4 stops an operation according to safety regulations. Accordingly, when a power outage occurs, electricity cannot be generated even in the presence of sunlight. However, from the user's point of view, when a power outage occurs, power generation through photovoltaic power generation is more necessary. Therefore, in recent years, there is a trend to install an ATS device to build a system that enables photovoltaic power generation even in the event of a power outage.

However, even if the ATS is installed, the photovoltaic power generation is unstable due to the influence of the environment such as weather. In order to compensate for this situation, the instability of the photovoltaic power generation can be overcome by installing the energy storage system 1 in parallel with the photovoltaic power generation to store and use the energy. That is, when more electricity than the amount of photovoltaic power generation is used, the energy storage system 1 may supplement the insufficient electricity. Alternatively, the power of energy storage system 1 can be used at night or in rainy weather when there is no photovoltaic power generation.

Even though power can be used with the energy stored in the energy storage system 1 during a short-term power outage, all of the energy stored in the energy storage system 1 is used during a long-term power outage, so that when the remaining capacity of the battery 35 falls to a safe use range or less, charging may not be achieved even if sunlight occurs the next day.

Therefore, in the present disclosure, a power blocking relay 1620 is provided in a point connected to the load side from a power source (sun light, energy storage system), and the state of charge of battery is monitored and managed, so that even if a long-term power outage occurs, photovoltaic power generation and energy storage system can be continuously used.

To implement this, when the battery management capacity range is set and a lower limit of a corresponding range is reached, the energy storage system 1 enters the power save mode and waits until the battery becomes chargeable.

According to an embodiment of the present disclosure, when a preset setting time is reached in the power save mode (S1770), the controller 1810 may generate a PV inverter driving signal (e.g., a reference voltage), and transmit the PV inverter driving signal to the PV inverter 4 (S1780).

The controller 1810 then checks whether the PV inverter 4 is started to generate power (S1740). If the generation power is not produced, corresponding operations (S1740 to S1780) are repeated with a specific time (setting time) period.

Meanwhile, when the state of charge of the battery rises to a specific value or more, the controller 1810 may turn on the load relay 1620 and supply power to the load 7y1 again.

The present disclosure proposes an energy storage system 1 that can be stably operated even during a power outage, and a power supply system including the same. In particular, according to the present disclosure, the energy storage system 1 can be used stably even in the case of a long-term power outage in which the power outage continues for a period of time (ex. 1 day) corresponding to one cycle during which the battery 35 is fully charged and discharged or more.

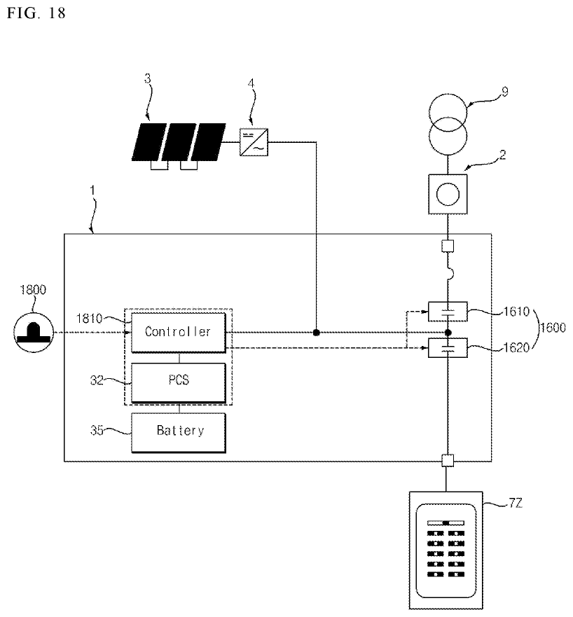

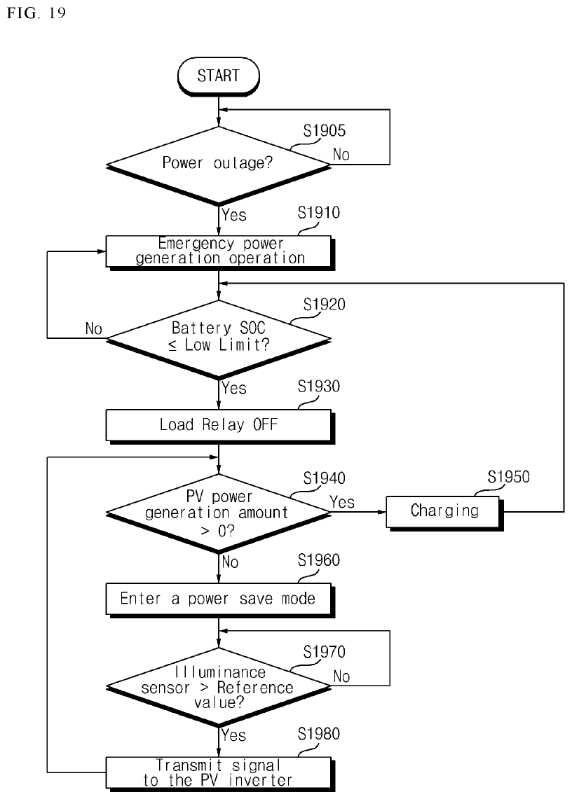

FIG. 18 is a conceptual diagram of an energy supplying system including an energy storage system according to a second embodiment of the present disclosure, and FIG. 19 is a flowchart of a method of operating an energy storage system according to the second embodiment of the present disclosure. In FIGS. 18 and 19, an illuminance sensor 1800 and related controls are added to the embodiment described with reference to FIGS. 16 and 17. Hereinafter, differences will be mainly described.

Referring to FIG. 18, the energy storage system 1 according to an embodiment of the present disclosure further includes the illuminance sensor 1800. The illuminance sensor 1800 may be installed to be exposed to the outside of the casing 12 or the enclosure 1b so as to determine whether there is sunlight for photovoltaic power generation. Alternatively, the illuminance sensor 1800 may be disposed outdoors or disposed adjacent to the photovoltaic panel 3, and may transmit a detected illuminance value by communicating with a communication module provided in the enclosure 1b.

When a power outage occurs (S1905), the controller 1810 controls the grid relay 1610 so that the energy storage system 1 switches to the emergency power generation operation mode and operates (S1910).

In the emergency power generation operation mode, the controller 1810 monitors whether the state of charge of battery falls to a preset low limit or less (S1920). The preset lower limit may be the above-described off-reference value.

Meanwhile, when the state of charge of battery falls to the lower limit or less (S1920), the controller 1810 may turn off the load relay 162 (S1930).

When the amount of power generated by the photovoltaic panel 3 exists in the state in which the load relay 162 is turned off (S1940), the battery 35 is charged with the power generated by the photovoltaic panel 3 (S1950).

When the amount of power generated by the photovoltaic panel 3 is zero (S1940), the controller 1810 may control the energy storage system 1 to enter a power save mode (S1960).

According to an embodiment of the present disclosure, it is determined whether there is sunlight through the illuminance sensor 1800, and only when photovoltaic power generation is possible (S1970), the photovoltaic inverter driving signal is transmitted to the photovoltaic inverter 4 (S1980).

If photovoltaic power generation is possible, the storage battery 35 is first charged with the power generated by the photovoltaic panel 3 (S1950), and until the state of charge of battery rises to a specific value (off-threshold or on-threshold) or more, the operation continues up to photovoltaic power generation from the comparison of the illuminance value detected by the illuminance sensor 1800 with an illuminance reference value. When the state of charge of the battery rises to a specific value or more, the controller 1810 may control the load relay 1620 to reconnect the power path connected to the load 7y1, thereby supplying power to the load 7y1.

When the illuminance value sensed by the illuminance sensor 1800 is measured below a specific value and thus photovoltaic power generation is not performed (S1940), the energy storage system 1 may enter the power save mode (S1960).

In the power save mode state, when the illuminance value detected by the illuminance sensor 1800 is higher than the illuminance reference value (S1970), the controller 1810 transmits the photovoltaic inverter driving signal to the photovoltaic inverter 4 to try photovoltaic power generation.

In the power save mode, the controller 1810 periodically monitors the value of the illuminance sensor 1800. When the illuminance value is measured to be a specific value or more, the controller 1810 transmits a reference voltage to the photovoltaic inverter 4 and then checks whether power is generated by photovoltaic power generation, and if power is generated, controls the battery 35 to be charged.

According to an embodiment of the present disclosure, it is possible to efficiently perform photovoltaic power generation and energy consumption by checking the presence or absence of sunlight.

According to an embodiment of the present disclosure, in the power save mode, when the illuminance value detected by the illuminance sensor 1800 is greater than the preset reference value (S1970), the controller 1810 may generate a PV inverter driving signal (ex. a reference voltage), and transmit to the PV inverter 4 (S1980).

The controller 1810 checks whether the PV inverter 4 is started to generate power (S1940). If the generation power is not produced, corresponding operations (S1940 to S1980) are repeated with a certain time period.

If the state of charge of the battery rises to a specific value or more, the controller 1810 may turn on the load relay 1620 and supply power to the load 7y1 again.

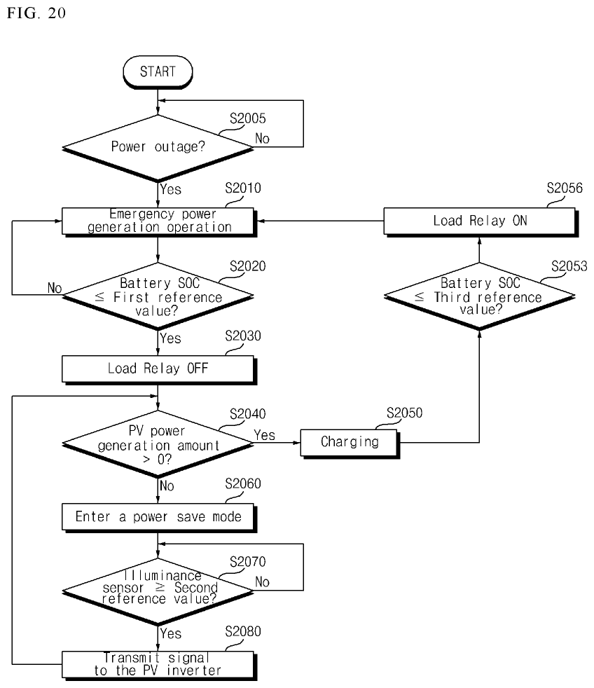

FIG. 20 is a flowchart of a method of operating an energy storage system according to a third embodiment of the present disclosure.

Referring to FIG. 20, when a power outage occurs in the grid 9 (S2005), the energy storage system 1 and the power supply system may enter an emergency power generation operation mode separated from the grid 9 (S2010).

Based on the state of charge (SoC) of battery and the amount photovoltaic power generation calculated by the battery management system 32 and/or the controller 1810 (S2020, S2040), the load relay 1620 may be controlled (S2030, S2056).

When the state of charge of battery is less than or equal to a first reference value (the above-mentioned off-reference value) (S2020), the controller 1810 turns off the load relay 1620 (S2030).

Meanwhile, when the amount of power generation of the photovoltaic panel 3 is 0 (S2040), the controller 1810 may control the energy storage system 1 to enter a power save mode (S2060).

In the power save mode, when the illuminance value detected by the illuminance sensor 1800 is equal to or greater than a preset second reference value (illuminance reference value) (S2070), the controller 1810 may generate a PV inverter driving signal (ex. reference voltage), and transmit to the PV inverter 4 (S2080).

Meanwhile, if power is generated from the photovoltaic panel 3 (S2040), the controller 1810 may control the battery 35 to be charged (S2050).

Meanwhile, as the battery 35 is charged (S2050), when the state of charge of battery is equal to or greater than the third reference value (on-reference value) (S2053), the controller 1810 turns on the load relay (S2030) to resume power supply (S2056).

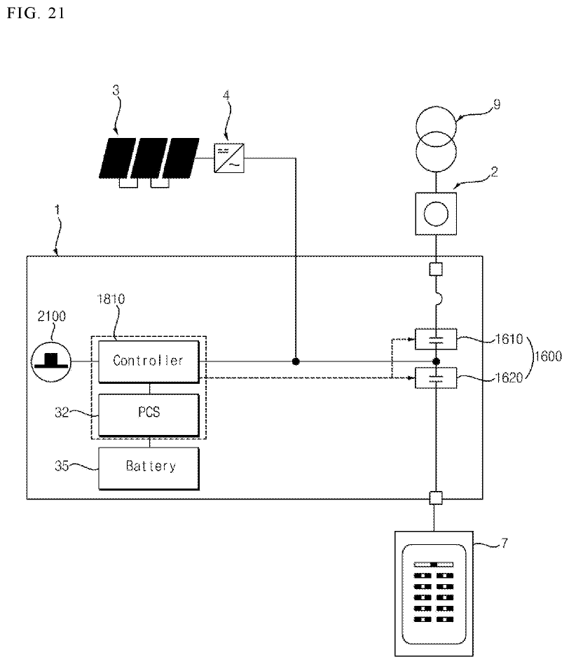

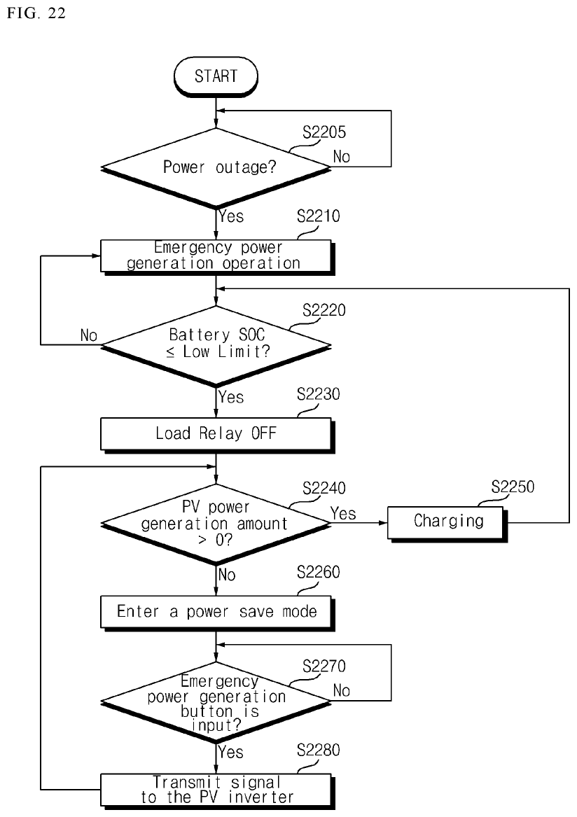

FIG. 21 is a conceptual diagram of an energy supplying system including an energy storage system according to a fourth embodiment of the present disclosure, and FIG. 22 is a flowchart of a method of operating an energy storage system according to the fourth embodiment of the present disclosure.

In FIGS. 21 and 22, the emergency power generation button 2100 and related controls are added to the embodiment described with reference to FIGS. 16 and 17. Hereinafter, differences will be mainly described.

Referring to FIG. 21, the energy storage system 1 according to an embodiment of the present disclosure further includes an emergency power generation button 2100. The emergency power generation button 2100 may be installed as a physical hardware button in the outside of the casing 12 or the enclosure 1b to receive a user input.

Referring to FIGS. 21 and 22, according to the occurrence of a power outage (S2205), the controller 1810 controls the grid relay 1610 so that the energy storage system 1 switches to the emergency power generation operation mode and operates (S2210).

In the emergency power generation operation mode, the controller 1810 monitors whether the state of charge of battery falls to a preset low limit or less (S2220). The preset lower limit may be the above-mentioned off-reference value.

Meanwhile, when the state of charge of battery falls to the lower limit or less (S2220), the controller 1810 may turn off the load relay 162 (S2230).

If the amount of power generated by the photovoltaic panel 3 exists in the state in which the load relay 162 is turned off (S2240), the battery 35 is charged with the power generated by the photovoltaic panel 3 (S2250).

When the amount of power generation of the photovoltaic panel 3 is 0 (S1940), the controller 1810 may control the energy storage system 1 to enter a power save mode (S2260).

According to an embodiment of the present disclosure, when a user identifies the presence of sunlight, and presses the emergency power button if it is determined that photovoltaic power generation is possible (S2270), the photovoltaic inverter driving signal can be transmitted to the photovoltaic inverter 4 (S2280).

If photovoltaic power generation is possible (S2240), the storage battery 35 is first charged with the power generated from the photovoltaic panel 3 (S2250). When the state of charge of the battery rises to a specific value (off-reference value or on-reference value) or more, the controller 1810 may turn on the load relay 1620 to supply power to the load 7y1.

Meanwhile, if photovoltaic power generation is not performed (S2240), the energy storage system 1 may enter a power save mode (S2260).

In the power save mode state (S2260), when there is an input to the emergency power generation button 2100 (S2270), the controller 1810 may transmit the photovoltaic inverter driving signal to the photovoltaic inverter 4 (S2280), and try photovoltaic power generation.

According to an embodiment of the present disclosure, photovoltaic power generation and energy consumption may be performed quickly and accurately in response to a user input.

The controller 1810 checks whether the PV inverter 4 is started to generate power (S2240). If the generation power is not produced, corresponding operations (S2240 to S2280) are repeated with a certain time period.

If the state of charge of the battery rises to a specific value or more, the controller 1810 may turn on the load relay 1620, and supply power to the load 7y1 again.

According to embodiments of the present disclosure, in the battery 35-based energy storage system 1 that operates in an emergency power generation operation (backup generation mode) due to a power outage, it is possible to solve a problem that the energy stored in the storage battery 35 is exhausted and the photovoltaic power generation is also stopped when the power outage is prolonged for one day or more.

According to embodiments of the present disclosure, the load relay 1620 controllable to connect or disconnect the load-side power path, the illuminance sensor 1800, and the emergency power generation button 2100 are provided and an algorithm to operate them is installed, thereby efficiently performing photovoltaic power generation and charging the battery stably.

According to at least one of the embodiments of the present disclosure, it is possible to stably operate the energy storage system even during a power outage.

According to at least one of the embodiments of the present disclosure, it is possible to efficiently supply emergency power to essential loads by controlling relays during a power outage.

In addition, according to at least one of the embodiments of the present disclosure, it is possible to efficiently use the energy stored in the battery during a power outage and recharge the battery again by using the photovoltaic generator.

In addition, according to at least one of the embodiments of the present disclosure, it is possible to determine a situation in which photovoltaic power generation and battery charging are possible during a power outage.

In addition, according to at least one of the embodiments of the present disclosure, the photovoltaic generator and the energy storage system may interwork with each other to efficiently produce, store, and manage energy.

In addition, according to at least one of the embodiments of the present disclosure, it is possible to respond to a long-term power outage by providing a means for multiply supplying emergency energy.

While the present invention has been particularly shown and described with reference to exemplary embodiments thereof, it will be understood by those of ordinary skill in the art that various changes in form and detail may be made herein without departing from the spirit and scope of the present invention as defined by the following claims and such modifications and variations should not be understood individually from the technical idea or aspect of the present invention.

What is claimed is:

1. An energy storage system connected to a grid power source and a photovoltaic panel, the energy storage system comprising:
a battery configured to store electric energy received from the grid power source or the photovoltaic panel in a direct current form, and to output the stored electric energy to one or more loads;
a grid relay configured to connect or block a power path connected to the grid power source; and
a load relay configured to connect or block a power path connected to the load,
wherein the grid relay is turned off based on an error occurring in the grid power source, and
the load relay is turned off based on a state of charge of the battery being lower than an off-reference value.

2. The energy storage system of claim 1, wherein the battery is charged with a power generated by the photovoltaic panel, based on power being generated by the photovoltaic panel.

3. The energy storage system of claim 2, wherein the load relay is turned on based on the state of charge of the battery being higher than the off-reference value.

4. The energy storage system of claim 2, wherein the load relay is turned on, based on the state of charge of the battery being higher than an on-reference value set higher than the off-reference value.

5. The energy storage system of claim 1, wherein the energy storage system is configured to operate in a power save mode in which only a preset minimum operation is performed, based on no power being generated by the photovoltaic panel.

6. The energy storage system of claim 5, wherein in the power save mode, based on a preset setting time being reached, a photovoltaic inverter driving signal is transmitted to a photovoltaic inverter that converts a power generated by the photovoltaic panel.

7. The energy storage system of claim 6, wherein the photovoltaic inverter driving signal is a signal corresponding to a voltage based on the grid power source being in a normal state.

8. The energy storage system of claim 5, further comprising an illuminance sensor,
wherein in a state of the power save mode, based on an illuminance value detected by the illuminance sensor being higher than an illuminance reference value, the photovoltaic inverter driving signal is transmitted to the photovoltaic inverter so as to convert a power generated by the photovoltaic panel.

9. The energy storage system of claim 8, wherein the photovoltaic inverter driving signal is a signal corresponding to a voltage based on the grid power source being in a normal state.

10. The energy storage system of claim 5, further comprising an emergency power button,
wherein in a state of the power save mode, based on there being an input to the emergency power button, the photovoltaic inverter driving signal is transmitted to the photovoltaic inverter so as to convert a power generated by the photovoltaic panel.

11. The energy storage system of claim 10, wherein the photovoltaic inverter driving signal is a signal corresponding to a voltage based on the grid power source being in a normal state.

12. The energy storage system of claim 1, further comprising a controller that controls the grid relay and the load relay so that, based on an error occurring in the grid power source, the electric energy generated by the photovoltaic panel or stored in the battery is supplied to a preset load.

13. The energy storage system of claim 1, further comprising:
a power conditioning system configured to convert electrical characteristics related to charging or discharging the battery; and
a battery management system configured to monitor state information of the battery.

14. The energy storage system of claim 13, further comprising a casing forming a space in which the battery, the power conditioning system, and the battery management system are disposed.

15. The energy storage system of claim 14, further comprising a power management system for controlling the power conditioning system,
wherein the power management system is disposed in an enclosure outside the casing.

16. The energy storage system of claim 15, wherein the power management system controls the grid relay and the load relay so that, based on an error occurring in the grid power source, the electric energy generated by the photovoltaic panel or stored in the battery is supplied to a preset load.

17. The energy storage system of claim 15, wherein the grid relay and the load relay are disposed in the enclosure.

18. The energy storage system of claim 1, further comprising a load panel connecting the load panel to a preset essential load.

19. The energy storage system of claim 1, wherein the off-reference value is set to be higher than a minimum state of charge in which the battery deteriorates to an unrecoverable state.

20. An energy supplying system comprising:
a photovoltaic panel; and
an energy storage system comprising a battery configured to store electric energy received from the grid power source or the photovoltaic panel in a direct current form, and to output the stored electric energy to one or more loads, a grid relay configured to connect or block a power path connected to the grid power source, and a load relay configured to connect or block a power path connected to the load,
wherein the grid relay is turned off based on an error occurring in the grid power source, and
the load relay is turned off based on a state of charge of the battery being lower than an off-reference value.
